(19) United States
(12) Patent Application Publication
(10) Pub. No.: US 2025/0151525 A1
(43) Pub. Date: May 8, 2025

(54) DISPLAY DEVICE INCLUDING FLOW-CONTROL LAYER AND METHOD OF PROVIDING THE SAME

(71) Applicant: Samsung Display Co., LTD., Yongin-si (KR)

(72) Inventors: So Yeon JEONG, Yongin-si (KR); Che Ho LEE, Yongin-si (KR); Sae Bom AHN, Yongin-si (KR); Won Je JO, Yongin-si (KR); Jae Hyun KIM, Yongin-si (KR)

(21) Appl. No.: 18/645,603

(22) Filed: Apr. 25, 2024

(30) Foreign Application Priority Data
Nov. 8, 2023 (KR) 10-2023-0153303

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes a display area including an emission area including a light emitting element, a non-emission area including a pixel defining layer defining a first opening corresponding to the light emitting element, and a bank on the pixel defining layer and defining a second opening corresponding to the first opening, the bank having a tip at the second opening, and a first encapsulation layer on the light emitting element and the bank, a non-display area adjacent to the display area, a flow-control layer in the display area and in the non-display layer, the flow-control layer including an auxiliary encapsulation layer in the display area, and a fluorine ion layer in the non-display area, and a second encapsulation layer extended along the flow-control layer, in the display area and in the non-display area.

This application claims priority to Korean Patent Application No. 10-2023-0153303 filed on Nov. 8, 2023, and all the benefits accruing therefrom under 35 U.S.C. 119, the contents of which in its entirety are herein incorporated by reference.

### BACKGROUND

### 1. Field

The present disclosure relates to a display device and a method of providing (or fabricating) the same.

### 2. Description of the Related Art

As the information society develops, demands for display devices for displaying images are increasing in various forms. The display devices may be flat panel display devices such as liquid crystal displays, field emission displays, and light emitting displays.

A display device includes a display area displaying images and a non-display area which is disposed along the display area, for example, surrounding the display area. A width of the non-display area has been gradually reduced to increase immersion in the display area and enhance aesthetic appearance of the display device.

In addition, with the development of various electronic devices, the demand for high-resolution display devices is increasing. Since high-resolution display devices have a high pixel density, a gap between light emitting elements respectively overlapping emission areas may be reduced. Therefore, a high-resolution display device may be provided (or formed) by a pattern process for forming individual structures of display pixels.

### SUMMARY

Aspects of the present disclosure are to maximize the area (e.g., the planar area) of a display area within a display device, by minimizing the area of a non-display area of the display device.

Aspects of the present disclosure also provide a high-resolution display device by providing (or forming) individual structures of display pixels, using a pattern process.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

In an embodiment of the disclosure, a display device includes a substrate including a display area, which includes an emission area and a non-emission area, and a non-display area, a light emitting element on the emission area of the substrate, a pixel defining layer located on the non-emission area of the substrate and defining a first opening, a bank structure located on the pixel defining layer and defining a second opening, a first encapsulation layer on the light emitting element and the bank structure, an auxiliary encapsulation layer on the first encapsulation layer, a fluorine ion layer on the non-display area of the substrate, and a second encapsulation layer on the auxiliary encapsulation layer and the fluorine ion layer, where the bank structure includes a first bank layer contacting the pixel defining layer and a second bank layer including a tip which protrudes more than a side surface of the first bank layer toward the emission area, the first encapsulation layer and the auxiliary encapsulation layer overlap the display area and do not overlap the non-display area, and the fluorine ion layer does not overlap the display area.

In an embodiment, the second encapsulation layer may include a first organic layer contacting the auxiliary encapsulation layer and a second organic layer contacting the fluorine ion layer.

In an embodiment, the spreadability of the first organic layer and the spreadability of the second organic layer may be different from each other.

In an embodiment, the spreadability of the first organic layer may be higher than the spreadability of the second organic layer.

In an embodiment, the first organic layer and the second organic layer may be spaced apart from each other and may be the same material.

In an embodiment, the spreadability of the first organic layer may be controlled by the auxiliary encapsulation layer, and the spreadability of the second organic layer may be controlled by the fluorine ion layer.

In an embodiment, the second organic layer may be formed in multiple pieces in a plan view and may have a round shape in a plan view.

In an embodiment, the fluorine ion layer may include fluorine ions on a surface.

In an embodiment, the auxiliary encapsulation layer may include any one of silicon oxide and silicon oxynitride.

In an embodiment, the oxygen content of the auxiliary encapsulation layer may be 35% or more.

In an embodiment, the first opening may be completely surrounded by the second opening in a plan view.

In an embodiment, the display device may further include a third encapsulation layer on the second encapsulation layer, where the third encapsulation layer overlaps the non-display area to completely cover the second organic layer and the fluorine ion layer and overlaps the non-display area to contact the second organic layer and the fluorine ion layer.

In an embodiment, the display device may further include a dam overlapping the non-display area and disposed between the substrate and the fluorine ion layer, where the fluorine ion layer covers the dam and contacts the dam.

In an embodiment of the disclosure, a display device includes a substrate including an emission area and a non-emission area, a pixel defining layer located on the non-emission area of the substrate, a first bank layer located on the pixel defining layer, a second bank layer located on the first bank layer and including a tip which protrudes toward the emission area, a firs anode on the emission area of the substrate, a first cathode located on the first anode and contacting the first bank layer, a first encapsulation layer on the first cathode and the second bank layer, and an auxiliary encapsulation layer on the first encapsulation layer, where the first encapsulation layer overlaps the emission area to contact the first bank layer, and the auxiliary encapsulation layer overlaps the non-display area to contact the second bank layer.

In an embodiment, the display device may further include a second anode spaced apart from the first anode with the pixel defining layer interposed therebetween, and a second cathode located on the second anode and contacting the first bank layer, where the first cathode and the second cathode are electrically connected by the first bank layer.

In an embodiment, the display device may further include a first electrode pattern located on the second bank layer, including the same material as the first cathode, and spaced apart from the first cathode, and a second electrode pattern located on the second bank layer, including the same material as the second cathode, and spaced apart from the second cathode.

In an embodiment, the second bank layer includes a first part contacting the first electrode pattern, a second part contacting the second electrode pattern, and a third part contacting the auxiliary encapsulation layer, where the first part and the second part are spaced apart from each other with the third part interposed therebetween.

In an embodiment, the first encapsulation layer may include a first inorganic layer covering the first cathode and the first electrode pattern, and a second inorganic layer covering the second cathode and the second electrode pattern, where the first inorganic layer and the second inorganic layer overlapping the non-emission area are spaced apart from each other in a direction parallel to the substrate.

In an embodiment of the disclosure, a method of fabricating a display device, the method including forming a substrate including a display area, which includes an emission area and a non-emission area, and a non-display area, forming an anode on the emission area of the substrate and a sacrificial layer on the anode, forming a pixel defining material layer covering the sacrificial layer and the substrate, and forming a bank material layer completely covering the pixel defining material layer, forming a photoresist on the bank material layer, forming a hole exposing the sacrificial layer by removing the pixel defining material layer and the bank material layer in a portion overlapping the anode through an etching process, and then forming a bank structure exposing the anode and including a tip which protrudes toward the emission area by removing an inner wall of the hole through an etching process, forming a light emitting layer and a cathode on the entire surface of the anode and the bank structure, forming a first encapsulation layer on the entire surface of the cathode, and then removing the light emitting layer, the cathode and the first encapsulation layer located on the bank structure except for the emission area and a portion around the emission area, forming an auxiliary encapsulation layer on the entire surface of the first encapsulation layer and the bank structure to overlap the display area and the non-display area and then removing the auxiliary encapsulation layer in a portion overlapping the non-display area through an etching process, and applying a second encapsulation layer on the auxiliary encapsulation layer to overlap the display area and the non-display area, where in the removing of the auxiliary encapsulation layer through the etching process, fluorine ions used in the etching process remain on the non-display area of the substrate to form a fluorine ion layer.

In an embodiment, the fluorine ion layer does not overlap the display area and contacts the second encapsulation layer.

According to an aspect of the present disclosure, there is provided

According to another aspect of the present disclosure, there is provided

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of an electronic device according to an embodiment;

FIG. 2 is a perspective view of a display device included in the electronic device according to the embodiment;

FIG. 3 is a schematic cross-sectional view of the display device of FIG. 2;

FIG. 4 is an enlarged plan view of area ‘A’ in FIG. 2;

FIG. 5 is a schematic cross-sectional view of a display layer taken along line X1-X1′ of FIG. 4;

FIG. 6 is an enlarged cross-sectional view of a non-emission area between a first emission area and a second emission area in FIG. 5;

FIG. 7 is an enlarged cross-sectional view of area ‘C’ in FIG. 6;

FIG. 8 is an enlarged cross-sectional view of area ‘T’ in FIG. 5;

FIG. 9 is an enlarged plan view of area ‘T’ in FIG. 5;

FIG. 10 is an enlarged cross-sectional view of area ‘A’ in FIG. 2 according to an embodiment;

FIG. 11 is a schematic cross-sectional view of a display area taken along line X3-X3′ of FIG. 10; and

FIGS. 12 through 22 are cross-sectional views illustrating a method of providing (or fabricating) the display device of FIG. 5.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

Like reference numerals refer to like elements throughout. Within the Figures and the text of the disclosure, a reference number indicating a singular form of an element may also be used to reference a plurality of the singular element.

It will be understood that when an element is referred to as being related to another element such as being “on” another element, it can be directly on the other element or intervening elements may be present therebetween. In contrast, when an element is referred to as being related to another element such as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, illustrative embodiments will be described with reference to the accompanying drawings.

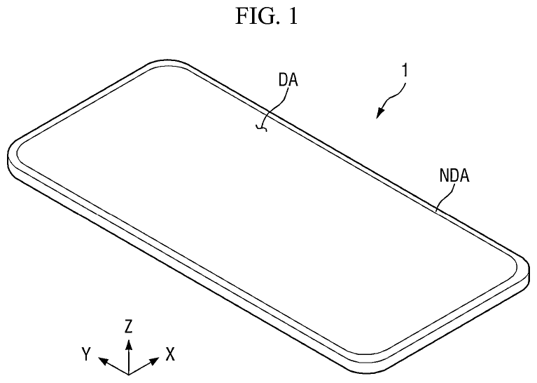

FIG. 1 is a schematic perspective view of an electronic device 1 according to an embodiment.

Referring to FIG. 1, the electronic device 1 displays moving images or still images. The electronic device 1 may refer to any electronic device that provides a display screen at which an image is displayed or visible from outside of the electronic device 1. Examples of the electronic device 1 may include televisions, notebook computers, monitors, billboards, Internet of things (IoT) devices, mobile phones, smartphones, tablet personal computers (PCs), electronic watches, smart watches, watch phones, head mounted displays, mobile communication terminals, electronic notebooks, electronic books, portable multimedia players (PMPs), navigation devices, game machines, digital cameras and camcorders, all of which provide a display screen.

In FIG. 1, a first direction (X-axis direction), a second direction (Y-axis direction), and a third direction (Z-axis direction) are defined. A plane may be defined by two directions crossing or intersecting each other. The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other, without being limited thereto. It may be understood that the first direction (X-axis direction) refers to a horizontal direction along a plane of the drawing, the second direction (Y-axis direction) refers to a vertical direction along the plane of the drawing, and the third direction (Z-axis direction) refers to an up-down direction into the plane of the drawing, that is, a thickness direction. In the following specification, unless otherwise specified, a “direction” may refer to both directions extending to opposing sides along a respective direction. In addition, when it is necessary to distinguish opposing “directions” extending to opposite sides, one side will be referred to as a “first side in the direction,” and the other side will be referred to as a “second side in the direction.” Based on FIG. 1, a direction in which an arrow is directed will be referred to as the first side, and a direction opposite to the direction will be referred to as the second side.

Hereinafter, for ease of description, in referring to surfaces of the electronic device 1 or each member constituting the electronic device 1, one surface facing the first side in a direction in which an image is displayed, that is, in the third direction (Z-axis direction) will be referred to as an upper surface, and the other surface opposite the one surface will be referred to as a lower surface. However, the present disclosure is not limited thereto, and the one surface and the other surface of each member may also be referred to as a front surface and a rear surface or as a first surface and a second surface, respectively. In addition, in describing relative positions of the members of the electronic device 1, the first side in the third direction (Z-axis direction) may be referred to as an upper side, and the second side in the third direction (Z-axis direction) may be referred to as a lower side.

The planar shape of the electronic device 1 can be variously modified. For example, the electronic device 1 may have various shapes in a plan view (or plane view) such as a horizontally long rectangle, a vertically long rectangle, a square, a quadrilateral with rounded corners (vertices), other polygons, and a circle.

The electronic device 1 may include a display area DA and a non-display area NDA which is adjacent to the display area DA. A boundary may be defined between the display area DA and the non-display area NDA. The display area DA is an area (e.g., a planar area) where a screen (e.g., a display screen) is defined and/or at which an image can be displayed, and the non-display area NDA is an area where no display screen is defined and/or no image is displayed. The display area DA may also be referred to as an active area, and the non-display area NDA may also be referred to as an inactive area. The display area DA may generally occupy a center of the electronic device 1, that is, being spaced apart from outer edges of the electronic device 1.

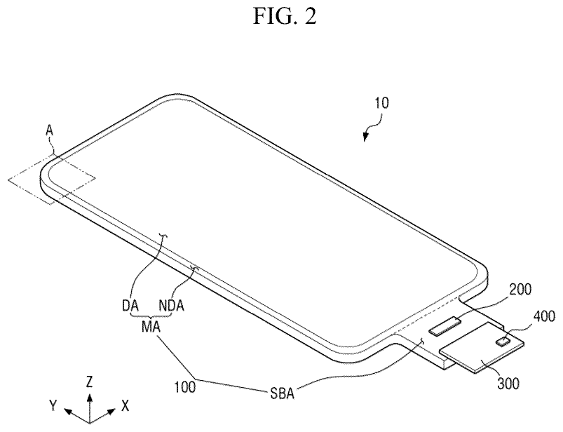

FIG. 2 is a perspective view of a display device 10 included in the electronic device 1 according to the embodiment.

Referring to FIG. 2, the electronic device 1 according to the embodiment may include the display device 10. The display device 10 may provide a screen which is displayed by the electronic device 1 (e.g., a display screen at which the image is displayed). The display device 10 may be, for example, an inorganic light emitting diode display device, an organic light emitting display device, a quantum dot light emitting display device, a plasma display panel, or a field emission display device. A case where an organic light emitting diode display device is applied as an example of the display device 10 will be described below, but the present disclosure is not limited to this case, and other display devices can also be applied as long as the same technical spirit is applicable.

The planar shape of the display device 10 may be similar to that of the electronic device 1. For example, the planar shape of the display device 10 may be similar to a rectangle having short sides in the first direction (X-axis direction) and long sides in the second direction (Y-axis direction). Each corner where a short side extending in the first direction (X-axis direction) meets a long side extending in the second direction (Y-axis direction) may be rounded with a predetermined curvature. However, the present disclosure is not limited thereto, and each corner may also be right-angled. The planar shape of the display device 10 is not limited to a quadrilateral shape but may also be similar to another polygonal shape, a circular shape, or an oval shape.

The display device 10 may include a display panel 100, a display driver 200, a circuit board 300, and a touch driver 400.

The display panel 100 may include a main area MA and a sub-area SBA which is adjacent to and extended from a side of the main area MA. The main area MA may include a display area DA including pixels PX which display an image, generate light, etc., and a non-display area NDA which is extended along the display area DA, such as to be disposed around the display area DA in the plan view.

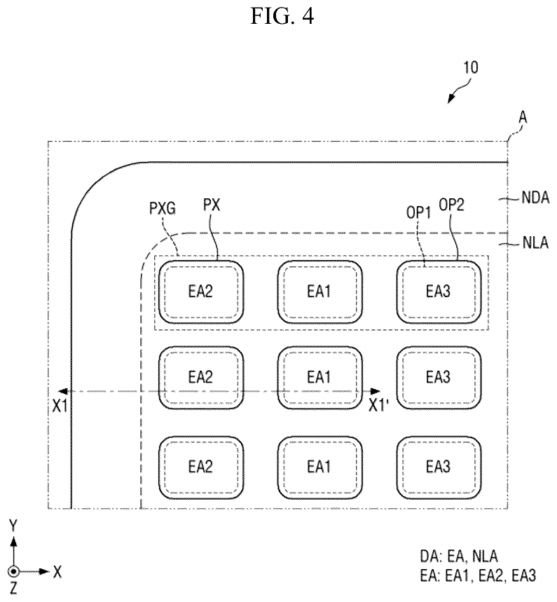

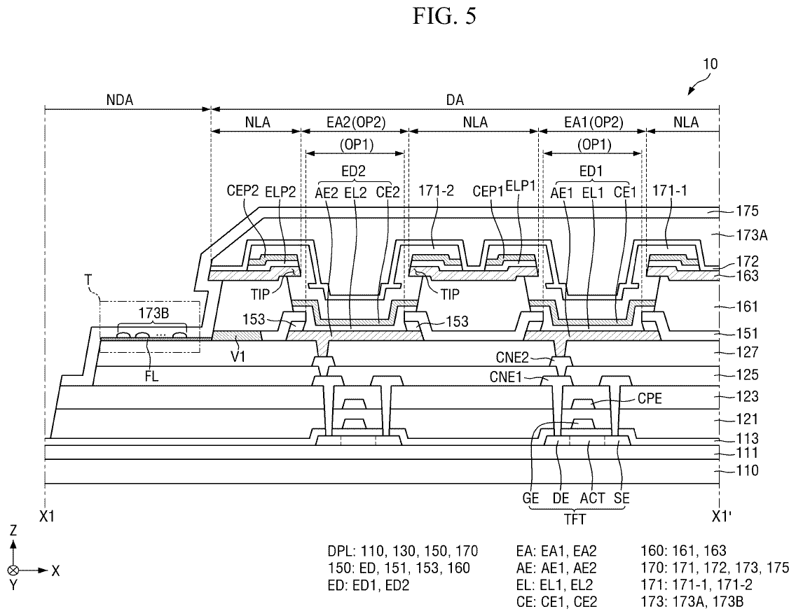

The display area DA may emit light from a plurality of emission areas EA (e.g., a light emission area provided in plural including a light emission areas) (see FIG. 4) which will be described later. For example, the display panel 100 may include a pixel defining layer 151 (see FIG. 5) and light emitting elements ED (see FIG. 5).

The non-display area NDA may be an area outside the display area DA, that is, closer to the outer edge of the electronic device 1 (or the display device 10) than the display area DA. The non-display area NDA may be defined as an edge area of the main area MA of the display panel 100.

The sub-area SBA may be an area extending from a side of the main area MA. The display panel 100 (or the display device 10) may be bendable at the sub-area SBA as a bending area. The sub-area SBA may include a flexible material which can be bent, folded, rolled, etc. For example, when the display device 10 is bent at the sub-area SBA, the sub-area SBA may be overlapped by the main area MA in the thickness direction (third direction (Z-axis direction)). The sub-area SBA may include the display driver 200 and a pad unit (not shown) at which the display device 10 is connected to the circuit board 300. In an embodiment, the sub-area SBA may be omitted, and the display driver 200 may be located in the non-display area NDA of the main area MA.

The display driver 200 may output signals and voltages for driving the display panel 100. The display driver 200 may be connected to the display area DA of the display panel 100, such as to the pixels PX. The display driver 200 may be provided (or formed) as an integrated circuit and mounted on the display panel 100 using a chip on glass (COG) method, a chip on plastic (COP) method, or an ultrasonic bonding method. For example, the display driver 200 may be disposed in the sub-area SBA and may be overlapped by the main area MA in the thickness direction, by the bending of the sub-area SBA. For another example, the display driver 200 may be mounted on the circuit board 300.

The circuit board 300 which is external to the display panel 100 may be attached onto the pad unit of the display panel 100, using an anisotropic conductive film. The circuit board 300 may be a flexible printed circuit board, a printed circuit board, or a flexible film such as a chip on film.

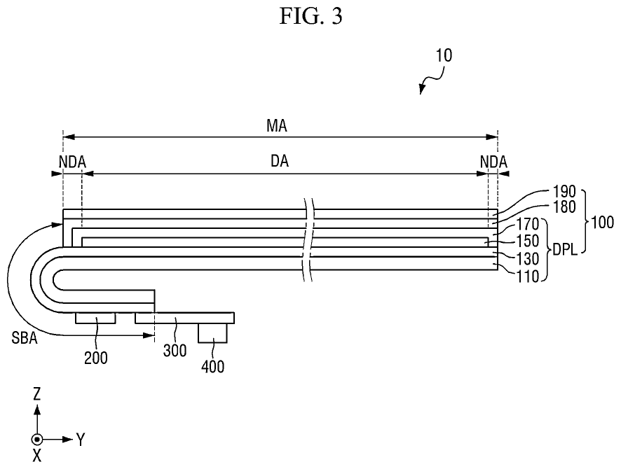

The touch driver 400 may be mounted on the circuit board 300. The touch driver 400 may be connected to a touch senor layer 180 (see FIG. 3) of the display panel 100. The touch driver 400 may be formed as an integrated circuit.

FIG. 3 is a schematic cross-sectional view of the display device 10 of FIG. 2.

Referring to FIG. 3, the display panel 100 may include a display layer DPL, the touch sensor layer 180, and a color filter layer 190. The display layer DPL which generates the light, generates the image, etc. (e.g., an image display layer) may include a substrate 110, a thin-film transistor layer 130 as a circuit layer, a display element layer 150, and a thin-film encapsulation layer 170 as an encapsulation layer.

The substrate 110 may be a base substrate or a base member. The substrate 110 may be a flexible substrate which can be bent, folded, rolled, etc. For example, the substrate 110 may include polymer resin such as polyimide (PI). However, the present disclosure is not limited thereto. In an embodiment, the substrate 110 may include a glass material or a metal material.

The thin-film transistor layer 130 may be disposed on the substrate 110. The thin-film transistor layer 130 may be disposed in the display area DA, the non-display area NDA, and the sub-area SBA. The thin-film transistor layer 130 may include a plurality of thin-film transistors TFT (see FIG. 5) constituting elements within pixels PX (see FIG. 4).

The display element layer 150 may be disposed on the thin-film transistor layer 130 and be electrically connected thereto. The display element layer 150 may overlap the display area DA. The display element layer 150 may include a plurality of light emitting elements ED (see FIG. 5). For example, each of the light emitting elements ED of an embodiment may include, but is not limited to, at least one of an organic light emitting diode including an organic light emitting layer, a quantum dot light emitting diode including a quantum dot light emitting layer, an inorganic light emitting diode including an inorganic semiconductor, and a micro-light emitting diode.

The thin-film encapsulation layer 170 may be located on the display element layer 150. The thin-film encapsulation layer 170 may overlap the display area DA and the non-display area NDA. The thin-film encapsulation layer 170 may cover upper and side surfaces of the display element layer 150 and may protect the display element layer 150 from external oxygen and moisture. The encapsulation layer may expose the bending area (e.g., the sub-area SBA) to outside the encapsulation layer. The thin-film encapsulation layer 170 may include at least one inorganic layer and at least one organic layer to encapsulate the display element layer 150.

The touch sensor layer 180 may be disposed on the thin-film encapsulation layer 170 The touch sensor layer 180 may overlap the display area DA and the non-display area NDA. The touch sensor layer 180 may sense an external input such as a user's touch, using a mutual capacitance method or a self-capacitance method.

The color filter layer 190 may be disposed on the touch sensor layer 180. The color filter layer 190 may overlap the display area DA and the non-display area NDA. The color filter layer 190 may reduce reflected light caused by external light by absorbing some of the light incident from the outside of the display device 10. Therefore, the color filter layer 190 can prevent color distortion caused by the reflection of external light.

In an embodiment, since the color filter layer 190 is directly disposed on the touch sensor layer 180, the display device 10 may not require a separate substrate for the color filter layer 190. Therefore, a thickness of the display device 10 may be relatively small. In addition, the color filter layer 190 can be omitted depending on embodiments.

As illustrated in FIG. 3, a portion of the display layer DPL which overlaps the sub-area SBA may be bendable, such as to be bent. When a portion of the display layer DPL is bent, the display driver 200, the circuit board 300, and the touch driver 400 may be overlapped by the main area MA in the third direction (Z-axis direction).

FIG. 4 is an enlarged plan view of area ‘A’ in FIG. 2.

Referring to FIG. 4, the display area DA may include emission areas EA (e.g., light emission areas) and a non-emission area NLA (e.g., a non-light emission area). The emission areas EA may include first emission areas EA1, second emission areas EA2, and third emission areas EA3 which emit light of different colors.

The non-emission area NLA may be adjacent to such as to surround each of the first through third emission areas EA1 through EA3. The non-emission area NLA may block light emitted from each of the first through third emission areas EA1 through EA3, to define a light blocking area. Therefore, the non-emission area NLA may help prevent the color mixing of light emitted from the first through third emission areas EA1 through EA3 at areas between the various light emission areas.

The first through third emission areas EA1 through EA3 may emit red light, green light and blue light, respectively. The color of light emitted from each of the first through third emission areas EA1 through EA3 may vary according to the type of light emitting element ED (see FIG. 5) overlapping the first, second or third emission area EA1, EA2 or EA3. In an embodiment, the first emission areas EA1 may emit red light, i.e., light of a first color, the second emission areas EA2 may emit green light, i.e., light of a second color, and the third emission areas EA3 may emit blue light, i.e., light of a third color, but the present disclosure is not limited thereto.

The first through third emission areas EA1 through EA3 may be defined by first openings OP1 and second openings OP2 of various layers of the display panel 100. For example, the first openings OP1 may be defined by the pixel defining layer 151 as an inorganic material layer (herein, an inorganic pixel defining layer 151) (see FIG. 5) which will be described later, and the second openings OP2 may be defined by a bank structure 160 of a collective bank layer (see FIG. 5) which will be described later. A boundary or edge of the second openings OP2 may completely surround the boundary or edge of the first openings OP1 in a plan view.

In some embodiments, at least one first emission area EA1, at least one second emission area EA2, and at least one third emission area EA3 disposed adjacent to each other may form a pixel group PXG. The pixel group PXG may be a smallest unit which emits white light. However, the types and/or number of the first through third emission areas EA1 through EA3 constituting the pixel group PXG may vary according to embodiments.

FIG. 5 is a schematic cross-sectional view of the display layer DPL taken along line X1-X1′ of FIG. 4. Cross sections of the substrate 110, the thin-film transistor layer 130, the display element layer 150, and the thin-film encapsulation layer 170 in the display layer DPL of an embodiment are illustrated. Since the substrate 110 has already been mentioned, a redundant description thereof will be omitted.

Referring to FIG. 5, the thin-film transistor layer 130 may be located on the substrate 110. The thin-film transistor layer 130 may include a first buffer layer 111, thin-film transistors TFT, a gate insulating layer 113, a first interlayer insulating layer 121, capacitor electrodes CPE, a second interlayer insulating layer 123, first connection electrodes CNE1, a first via layer 125, second connection electrodes CNE2, and a second via layer 127.

The first buffer layer 111 may be disposed on the substrate 110. The first buffer layer 111 may be disposed in portions overlapping the display area DA and the non-display area NDA. The first buffer layer 111 may include an inorganic layer which can prevent the penetration of air or moisture. For example, the first buffer layer 111 may include a plurality of inorganic layers stacked alternately.

The thin-film transistors TFT may be disposed on the first buffer layer 111 and may constitute pixel circuits respectively connected to a plurality of pixels PX. The thin-film transistors TFT may be disposed in the portion overlapping the display area DA. For example, each of the thin-film transistors TFT may be a driving transistor or a switching transistor of a pixel circuit. Each of the thin-film transistors TFT may include an active layer ACT, a source electrode SE, a drain electrode DE, and a gate electrode GE.

The active layer ACT may be disposed on the first buffer layer 111. The active layer ACT may be overlapped by the gate electrode GE in the third direction (Z-axis direction) and may be insulated from the gate electrode GE by the gate insulating layer 113. The material of the active layer ACT may be made conductive in portions of the active layer ACT to form the source electrode SE and the drain electrode DE.

The gate electrode GE may be disposed on the gate insulating layer 113. The gate electrode GE may overlap the active layer ACT with the gate insulating layer 113 interposed between them.

The gate insulating layer 113 may be disposed on the active layers ACT. The gate insulating layer 113 may be disposed in the portions overlapping the display area DA and the non-display area NDA. The gate insulating layer 113 may cover the active layers ACT and the first buffer layer 111 and may insulate the active layers ACT from the gate electrodes GE. The gate insulating layer 113 may include contact holes through which the first connection electrodes CNE1 pass.

The first interlayer insulating layer 121 may cover the gate electrodes GE and the gate insulating layer 113. The first interlayer insulating layer 121 may be disposed in the portions overlapping the display area DA and the non-display area NDA. The first interlayer insulating layer 121 may include (or define therein) contact holes through which the first connection electrodes CNE1 pass. The contact holes of the first interlayer insulating layer 121 may be connected to the contact holes of the gate insulating layer 113 and contact holes of the second interlayer insulating layer 123. As used herein, more than one layer among layers 111-127 may be referred to as “an insulating layer,” for convenience of explanation.

The capacitor electrodes CPE may be disposed on the first interlayer insulating layer 121. The capacitor electrodes CPE may overlap the gate electrodes GE in the third direction (Z-axis direction). The capacitor electrodes CPE and the gate electrodes GE may form an electrical capacitance.

The second interlayer insulating layer 123 may cover the capacitor electrodes CPE and the first interlayer insulating layer 121. The second interlayer insulating layer 123 may be disposed in the portions overlapping the display area DA and the non-display area NDA. The second interlayer insulating layer 123 may include the contact holes through which the first connection electrodes CNEl pass in the portion overlapping the display area DA. The contact holes of the second interlayer insulating layer 123 may be connected to the contact holes of the first interlayer insulating layer 121 and the contact holes of the gate insulating layer 113.

The first connection electrodes CNE1 may be disposed on the second interlayer insulating layer 123. The first connection electrodes CNE1 may electrically connect the drain electrodes DE of the thin-film transistors TFT to the second connection electrodes CNE2. The first connection electrodes CNE1 may be inserted into (or extend through) the contact holes formed in the first interlayer insulating layer 121, the second interlayer insulating layer 123 and the gate insulating layer 113 to contact the drain electrodes DE of the thin-film transistors TFT.

The first via layer 125 may cover the first connection electrodes CNE1 and the second interlayer insulating layer 123. The first via layer 125 may be disposed in the portions overlapping the display area DA and the non-display area NDA. The first via layer 125 may planarize structures thereunder. The first via layer 125 may include contact holes through which the second connection electrodes CNE2 pass in the portion overlapping the display area DA.

The second connection electrodes CNE2 may be disposed on the first via layer 125. The second connection electrodes CNE2 may be inserted into the contact holes formed in the first via layer 125 to contact the first connection electrodes CNE1. The second connection electrodes CNE2 may electrically connect the first connection electrodes CNE1 to anodes AE. As being in contact, elements may be in physical contact, such as to form an interface therebetween.

The second via layer 127 may cover the second connection electrodes CNE2 and the first via layer 125. The second via layer 127 may be disposed in the portions overlapping the display area DA and the non-display area NDA. The second via layer 127 may include contact holes through which the anodes AE pass in the portion overlapping the display area DA.

The display element layer 150 may be disposed on the second via layer 127. The display element layer 150 of an embodiment may include the light emitting elements ED, the inorganic pixel defining layer 151, residual patterns 153, and the bank structure 160.

Each of the light emitting elements ED may include an anode AE, a light emitting layer EL, and a cathode CE. The light emitting elements ED may include a first light emitting element ED1 disposed in a first emission area EA1 and a second light emitting element ED2 disposed in a second emission area EA2. For example, the first light emitting element ED1 may emit red light, and the second light emitting element ED2 may emit green light, but the present disclosure is not limited thereto.

The anodes AE may be disposed on the second via layer 127. The anodes AE may be electrically connected to the drain electrodes DE of the thin-film transistors TFT through the first connection electrodes CNE1 and the second connection electrodes CNE2.

The anodes AE may include a first anode AE1 disposed in the first emission area EA1 and a second anode AE2 disposed in the second emission area EA2. The first anode AE1 and the second anode AE2 may be spaced apart from each other on (or along) the second via layer 127.

In an embodiment, the anodes AE may have a stacked structure of a material layer having a high work function such as indium-tin-oxide (ITO), indium-zinc-oxide (IZO), zinc oxide (ZnO) or indium oxide (In₂O₃) and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca) or a mixture thereof. For example, the anodes AE may have, but are not limited to, a multilayer structure of ITO/Mg, ITO/MgF, ITO/Ag, or ITO/Ag/ITO.

The inorganic pixel defining layer 151 may be located on the second via layer 127 and the anodes AE. The inorganic pixel defining layer 151 may separate and insulate the first anode AE1 and the second anode AE2 from each other. The inorganic pixel defining layer 151 of an embodiment may define the first openings OP1. Here, a sidewall (or side surface) of the pixel defining layer 151 may define a first opening OP1. The inorganic pixel defining layer 151 may be disposed on the entire surface of the second via layer 127, but may partially expose upper surfaces of the anodes AE to outside the pixel defining layer 151. In other words, the inorganic pixel defining layer 151 may expose the anodes AE in portions overlapping the first openings OP1, and the light emitting layers EL may be directly disposed on the anodes AE in the portions overlapping the first openings OP1.

In some embodiments, a solid portion of the inorganic pixel defining layer 151 which is closest to the non-display area NDA, to be adjacent to the non-display area NDA, may be disposed adjacent to a power line V1. The power line V1 may supply a power supply voltage received from the display driver 200 (see FIG. 3) to the first light emitting element ED1 and the second light emitting element ED2.

The inorganic pixel defining layer 151 may include an inorganic insulating material. For example, the inorganic pixel defining layer 151 may include aluminum oxide, titanium oxide, tantalum oxide, hafnium oxide, zinc oxide, silicon oxide, silicon nitride, or silicon oxynitride.

The bank structure 160 may be located on the inorganic pixel defining layer 151. The bank structure 160 may be disposed in a portion overlapping the non-emission area NLA. That is, a solid material portion of the bank structure 160 may correspond to the non-emission area NLA. The bank structure 160 of an embodiment may include a first bank layer 161 and a second bank layer 163 disposed on the inorganic pixel defining layer 151. The bank structure 160 may have a structure in which the first bank layer 161 and the second bank layer 163 are sequentially stacked in the third direction (Z-axis direction). The first bank layer 161 and the second bank layer 163 may include different conductive materials. The first bank layer 161 and the second bank layer 163 may together define a bank of the bank structure 160, that is, a solid portion of a collective bank layer which defines bank openings of the collective bank layer.

The bank structure 160 may include (or define) tips TIP protruding toward the emission areas EA. An inner sidewall or inner side surface of the bank may define a respective emission area EA. In the display device 10 of an embodiment, since the bank structure 160 includes the tips TIP, patterns of the first light emitting element ED1 and the second light emitting element ED2 respectively overlapping the first emission area EA1 and the second emission area EA2 can be provided (or formed) without a fine metal mask in a process of fabricating the display device 10. The fabrication process will be described later.

The bank structure 160 of an embodiment may define the second openings OP2. The emission areas EA of an embodiment may be defined by or correspond to the second openings OP2. Specifically, the second bank layer 163 as an upper thickness portion of a bank of an embodiment may define the second openings OP2.

The light emitting layers EL may be respectively disposed on the anodes AE. The light emitting layers EL may be organic light emitting layers or patterns made of (or including) an organic material, and may be formed on the anodes AE through a deposition process. When the thin-film transistors TFT apply a predetermined voltage to the anodes AE and the cathodes CE receive a common voltage or a cathode voltage, holes and electrons may move to the light emitting layers EL through hole transport layers and electron transport layers, respectively, and may be combined with each other in the light emitting layers EL to emit light at the various emission areas EA.

The light emitting layers EL may include a first light emitting layer EL1 disposed in the first emission area EA1 and a second light emitting layer EL2 disposed in the second emission area EA2. For example, the first light emitting layer EL1 may emit red light, and the second light emitting layer EL2 may emit green light, but the present disclosure is not limited thereto.

In some embodiments, the anodes AE may be spaced apart from the inorganic pixel defining layer 151 in the third direction (Z-axis direction), to define a gap or a space between facing surfaces of the the anodes AE may be spaced apart from the inorganic pixel defining layer 151. The residual patterns 153 may be located in the spaces between the anodes AE and the inorganic pixel defining layer 151. The residual patterns 153 will be described later.

The cathodes CE may be disposed on the light emitting layers EL. The cathodes CE may include a transparent conductive material to transmit light generated from the light emitting layers EL. The cathodes CE may receive a common voltage or a low-potential voltage. When the anodes AE receive a voltage corresponding to a data voltage and the cathodes CE receive a low-potential voltage, a potential difference may be formed between the anodes AE and the cathodes CE. Accordingly, the light emitting layers EL may emit light.

In an embodiment, the cathodes CE may include a material layer having a small work function such as Li, Ca, LiF/Ca, LiF/Al, Al, Mg, Ag, Pt, Pd, Ni, Au Nd, Ir, Cr, BaF, Ba, or a compound or combination thereof (e.g., a mixture of Ag and Mg). The cathodes CE may further include a transparent metal oxide layer disposed on the material layer having a small work function.

The cathodes CE may include a first cathode CE1 disposed in the first emission area EA1 and a second cathode CE2 disposed in the second emission area EA2. The first cathode CE1 may be disposed on the first light emitting layer EL1 in the first emission area EA1, and the second cathode CE2 may be disposed on the second light emitting layer EL2 in the second emission area EA2.

The first cathode CE1 and the second cathode CE2 may not be directly connected to each other, but may be electrically connected to each other through the first bank layer 161. In other words, the cathodes CE as discrete patterns separated from each other may receive a power supply voltage from the display driver 200 (see FIG. 3) through the power line V1 and the first bank layer 161, and the first cathode CE1 and the second cathode CE2 may be electrically connected to each other through the first bank layer 161.

A first organic pattern ELP1 and a second organic pattern ELP2 may be located on the bank structure 160. The first organic pattern ELP1 and the second organic pattern ELP2 may surround the first openings OP1 in the plan view. The first organic pattern ELP1 and the second organic pattern ELP2 may include the same material as the first light emitting layer EL1 and the second light emitting layer EL2, respectively. The first organic pattern ELP1 and the second organic pattern ELP2 may be traces of material formed as an organic material layer for forming the first light emitting layer EL1 and the second light emitting layer EL2 is separated by or at the tips TIP included in the bank structure 160.

Here, the first organic pattern ELP1, the second organic pattern ELP2, the first light emitting layer EL1 and the second light emitting layer EL2 may be in a same layer as each other. As being in a same layer, elements may be formed in a same process and/or include a same material as each other, elements may be respective portions of a same material layer, elements may be on a same layer by forming an interface with a same underlying or overlying layer, etc., without being limited thereto.

A first electrode pattern CEP1 and a second electrode pattern CEP2 may be disposed on the first organic pattern ELP1 and the second organic pattern ELP2, respectively. The arrangement relationship between the first and second electrode patterns CEP1 and CEP2 and the first and second organic patterns ELP1 and ELP2 may be the same as the arrangement relationship between the first and second light emitting layers EL1 and EL2 and the first and second cathodes CE1 and CE2. The first electrode pattern CEP1 and the second electrode pattern CEP2 may include the same material as the first cathode CE1 and the second cathode CE2, respectively, to be in a same layer as each other. The first electrode pattern CEP1 and the second electrode pattern CEP2 may be traces formed as the first cathode CE1 and the second cathode CE2 are separated by the tips TIP included in the bank structure 160. In an embodiment, a conductive pattern layer includes the first cathode CE1 and the second cathode CE2 in respective emission areas, and in the non-emission area NLA, a first electrode pattern CEP1 on the bank and spaced apart from the first cathode CE1 and a second electrode pattern CEP2 on the bank and spaced apart from the second cathode CE2.

The thin-film encapsulation layer 170 may be disposed on the display element layer 150. The thin-film encapsulation layer 170 may include a first encapsulation layer 171, an auxiliary encapsulation layer 172, a second encapsulation layer 173, and a third encapsulation layer 175 stacked sequentially. The first encapsulation layer 171, the auxiliary encapsulation layer 172, and the third encapsulation layer 175 may be inorganic encapsulation layers, and the second encapsulation layer 173 may be an organic encapsulation layer.

The first encapsulation layer 171 of an embodiment may be disposed in the portion overlapping the display area DA. In other words, the first encapsulation layer 171 of the embodiment may not overlap the non-display area NDA. As not overlapping, elements may be adjacent to each other and/or spaced apart from each other in planar direction, such as along an X-Y plane The first encapsulation layer 171 may protect the light emitting elements ED from moisture and oxygen.

The first encapsulation layer 171 of an embodiment may include a first inorganic layer 171-1 and a second inorganic layer 171-2. The first inorganic layer 171-1 and the second inorganic layer 171-2 may be located in portions overlapping the first emission area EA1 and the second emission area EA2, respectively. For example, the first inorganic layer 171-1 may cover the first light emitting element ED1 and the first electrode pattern CEP1, and the second inorganic layer 171-2 may cover the second light emitting element ED2 and the second electrode pattern CEP2. The first inorganic layer 171-1 and the second inorganic layer 171-2 may be spaced apart from each other in the first direction (X-axis direction) in the portion overlapping the non-emission area NLA. While spacing along the X-axis direction is shown in FIG. 5, the above-described spacing may also be defined along the Y-axis direction, or various directions within the X-Y plane.

Although the first inorganic layer 171-1 and the second inorganic layer 171-2 are formed on the same layer in the drawing, they may be formed in different processes. For example, the first inorganic layer 171-1 may be formed after the first cathode CE1 is formed, and the second inorganic layer 171-2 may be formed after the second cathode CE2 is formed. The fabrication process will be described later.

The first encapsulation layer 171 may include one or more inorganic insulating materials. The inorganic insulating materials may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The auxiliary encapsulation layer 172 of an embodiment may be disposed in the portion overlapping the display area DA. In other words, the auxiliary encapsulation layer 172 of the embodiment may not overlap the non-display area NDA. The auxiliary encapsulation layer 172 may improve the spreadability of a material forming the second encapsulation layer 173 in one or more planar direction along the display element layer 150. That is, the auxiliary encapsulation layer 172 may help the second encapsulation layer 173 have high spreadability in a process of providing the encapsulation layer.

The auxiliary encapsulation layer 172 may include an inorganic insulating material containing oxygen ions. For example, the auxiliary encapsulation layer 172 may include any one of silicon oxide (SiO₂) and silicon oxynitride (Si₂N₂O). The oxygen ion content of the auxiliary encapsulation layer 172 may be about 35% or more when measured by Fourier transform infrared spectroscopy.

The second encapsulation layer 173 of an embodiment may overlap the display area DA and the non-display area NDA. The second encapsulation layer 173 of the embodiment may include a first organic layer 173A overlapping the display area DA and a second organic layer 173B overlapping the non-display area NDA. The first organic layer 173A and the second organic layer 173B may be spaced apart from each other in a direction along the display element layer 150, and the spreadability of a material for forming the first organic layer 173A and the second organic layer 173B may be adjusted according to structures disposed under and in contact with the first organic layer 173A and the second organic layer 173B. In an embodiment, a material of each of the first organic layer 173A and the second organic layer 173B has a spreadability relative to a flow-control layer (172 and FL), and the spreadability of the material of the first organic layer 173A and the spreadability of the material of the second organic layer 173B may be different from each other. The spreadability of the material of the first organic layer 173A may be higher than the spreadability of the material of the second organic layer 173B. Where the first organic layer 173A and the second organic layer 173B are respective portions of a same material layer, the spreadability of the material of the first organic layer 173A is defined by contact of the material of the first organic layer 173A along the auxiliary encapsulation layer 172, and the spreadability of the material of the second organic layer 173B is defined by contact of the material of the second organic layer 173B along the fluorine ion layer FL.

For example, the first organic layer 173A may be disposed on the auxiliary encapsulation layer 172 and may contact the auxiliary encapsulation layer 172. The spreadability of the first organic layer 173A may be higher than that of the second organic layer 173B. Accordingly, the first organic layer 173A may fill and planarize steps of the structure disposed under and overlapped by the first organic layer 173A.

The second organic layer 173B may be disposed on a fluorine ion layer FL and may contact the fluorine ion layer FL. The spreadability of the second organic layer 173B may be lower than that of the first organic layer 173A, and the second organic layer 173B may be formed in the form of a plurality of round shapes spaced apart from each other. That is, the second organic layer 173B may be defined by protrusions arranged along a pattern of the fluorine ion layer FL. The protrusions may be discrete patterns spaced apart from each other along a plane of the fluorine ion layer FL.

The fluorine ion layer FL may be disposed on the second via layer 127 in the portion overlapping the non-display area NDA and may include fluorine ions on a surface. Here, the fluorine ions may be exposed to outside the fluorine ion layer FL. The fluorine ion layer FL may be flat, such as to extend in a single plane. An upper surface of the fluorine ion layer FL may be flat.

The second encapsulation layer 173 may include a polymer-based material. Examples of the polymer-based material may include acrylic resin, epoxy resin, polyimide, and polyethylene. For example, the second encapsulation layer 173 may include acrylic resin such as polymethyl methacrylate or polyacrylic acid. The second encapsulation layer 173 may be formed by curing a monomer or applying a polymer.

The third encapsulation layer 175 may be disposed in the portions overlapping the display area DA and the non-display area NDA. The third encapsulation layer 175 may completely cover the first organic layer 173A and the second organic layer 173B of the second encapsulation layer 173. The third encapsulation layer 175 may be disposed in the display area DA and extend from the display area DA to be disposed in the non-display area NDA and completely cover the discrete patterns forming the second organic layer 173B in the non-display area NDA. The third encapsulation layer 175 may protect the display element layer 150 from oxygen and moisture.

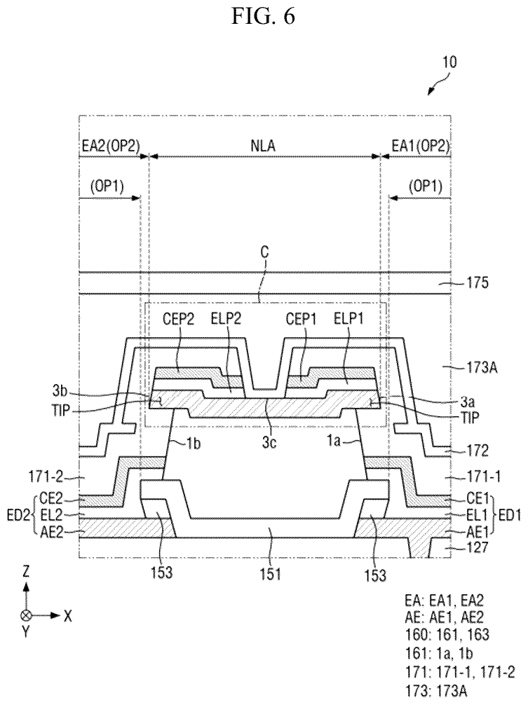

FIG. 6 is a schematic enlarged cross-sectional view of the non-emission area NLA disposed between the first emission area EA1 and the second emission area EA2 in FIG. 5.

Referring to FIG. 6, in an embodiment, the first emission area EA1 and the second emission area EA2 may be spaced apart from each other with the non-emission area NLA interposed between them. As described above, in an embodiment, the first openings OP1 may be defined by the inorganic pixel defining layer 151, and the second openings OP2 may be defined by the second bank layer 163.

The first bank layer 161 of an embodiment of a bank may be disposed on the inorganic pixel defining layer 151 to contact the inorganic pixel defining layer 151. The first bank layer 161 of the embodiment may include a material having excellent electrical conductivity. Accordingly, the first bank layer 161 may electrically connect the first cathode CE1 and the second cathode CE2 spaced apart from each other and disposed in the first emission area EA1 and the second emission area EA2, respectively, to each other. For example, the first bank layer 161 may include at least one of aluminum (Al) and copper (Cu).

In some embodiments, the first bank layer 161 may include a first side surface 1a facing the first emission area EA1 and a second side surface 1b facing the second emission area EA2. At an emission area EA, the first side surface 1a of the first bank layer 161 may be more recessed than the sidewall of the inorganic pixel defining layer 151, toward the second side in the first direction (X-axis direction), and the second side surface 1b of the first bank layer 161 may be more recessed than the inorganic pixel defining layer 151 toward the first side in the first direction (X-axis direction). This may result from the fact that the first bank layer 161 of the embodiment includes a material having a relatively higher etch rate than that of the inorganic pixel defining layer 151. That is, the sidewalls of the bank at the first bank layer 161, may be recessed from sidewalls of the inorganic pixel defining layer 151, to define an exposed portion of the inorganic pixel defining layer 151 which is exposed to the bank opening.

In an embodiment, within an emission area EA, the first light emitting layer EL1, the first cathode CE1 and the first inorganic layer 171-1 may contact the first side surface 1a, and the second light emitting layer EL2, the second cathode CE2 and the second inorganic layer 171-2 may contact the second side surface 1b.

The second bank layer 163 of an embodiment of the bank may be disposed on the first bank layer 161 to contact the first bank layer 161. The second bank layer 163 of the embodiment may include a metal material having high electrical stability and high adhesion to metal. For example, the second bank layer 163 may include any one of molybdenum (Mo), chromium (Cr), gold (Au), titanium (Ti), nickel (Ni) and neodymium (Nd) and an alloy thereof.

In some embodiments, the second bank layer 163 may include a first side surface 3a at a same side of the bank as the first side surface 1a and facing the first emission area EA1, a second side surface 3b at a same side of the bank as the second side surface 1b and facing the second emission area EA2, and a first surface 3c as an uppermost surface of the bank. The first side surface 3a of the second bank layer 163 may protrude more than the first side surface 1a of the first bank layer 161, in a direction toward the first emission area EA1, and the second side surface 3b of the second bank layer 163 may protrude more than the second side surface 1b of the first bank layer 161, in a direction toward the second emission area EA2. That is, sidewalls of the second bank layer 163 protrude further than sidewall of the first bank layer 161, at respective emission areas EA. In addition, the first surface 3c may connect the first side surface 3a and the second side surface 3b to each other. The first surface 3c will be described later. The bank sidewalls at the first bank layer 161 and the second bank layer 163 may together define a bank opening of the collective bank layer.

The second bank layer 163 may include a metal material which is relatively more stable than that of the first bank layer 161, with respect ton an etching process during the process of fabricating the display device 10. In other words, an etch rate of the second bank layer 163 may be lower than an etch rate of the first bank layer 161. Accordingly, the first side surface 3a and the second side surface 3b of the second bank layer 163 may protrude further than respective side surfaces at the first bank layer 161 in the direction toward the emission areas EA. In other words, the second bank layer 163 may define the tips TIP as extended portions protruding further than respective side surfaces of the first bank layer 161, in both of opposing directions (e.g., to both sides toward the first emission area EA1 and the second emission area EA2), and an undercut may be formed by the the first bank layer 161 and each tip TIP as an extended portion of the second bank layer 163. Here, an exposed portion of the second bank layer 163 which is exposed to the bank opening may be defined.

In some embodiments, a height. Referring to FIG. 6, for example, with respect to a common surface or plane, a thickness of the first bank layer 161 in the third direction (Z-axis direction) may be greater than a thickness of the second bank layer 163.

The residual patterns 153 of an embodiment may be disposed in the gap between the first anode AE1 and the inorganic pixel defining layer 151 in the third direction (Z-axis direction) and may be disposed in the gap between the second anode AE2 and the inorganic pixel defining layer 151 in the third direction (Z-axis direction). In addition, the residual patterns 153 of the embodiment may be overlapped by the protruding tips TIP of the bank structure 160 in the third direction (Z-axis direction). A gap may be defined between the exposed (lower surface) portion at the TIP and the exposed (upper surface) portion of the inorganic pixel defining layer 151, and such gap may define a recess open to a respective bank opening or emission area EA.

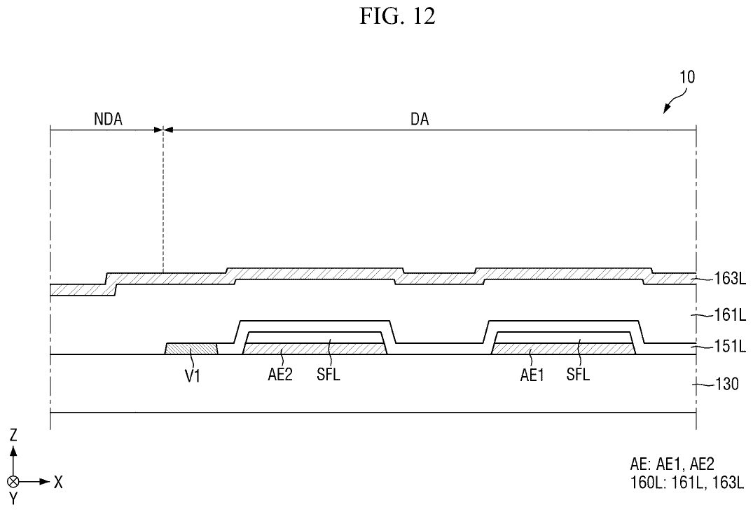

The display device 10 according to the embodiment may include a sacrificial layer SFL (see FIG. 12) between the inorganic pixel defining layer 151 and each anode AE in the fabrication process. The sacrificial layer SFL may be disposed between the inorganic pixel defining layer 151 and the first anode AE1 and between the inorganic pixel defining layer 151 and the second anode AE2 and then may be partially removed by a subsequent wet etching process. Here, unremoved portions of the sacrificial layer SFL may remain between the inorganic pixel defining layer 151 and the first anode AE1 and between the inorganic pixel defining layer 151 and the second anode AE2 as the residual patterns 153.

In an embodiment, the first cathode CE1 may completely cover the first light emitting layer EL1, and the second cathode CE2 may completely cover the second light emitting layer EL2. In addition, the first inorganic layer 171-1 of an embodiment may completely cover the first light emitting element ED1 in the portion overlapping the first emission area EA1 and may partially cover the first organic pattern ELP1 and the first electrode pattern CEP1 in the portion overlapping the non-emission area NLA. In addition, the second inorganic layer 171-2 of an embodiment may completely cover the second light emitting element ED2 in the portion overlapping the second emission area EA2 and may partially cover the second organic pattern ELP2 and the second electrode pattern CEP2 in the portion overlapping the non-emission area NLA.

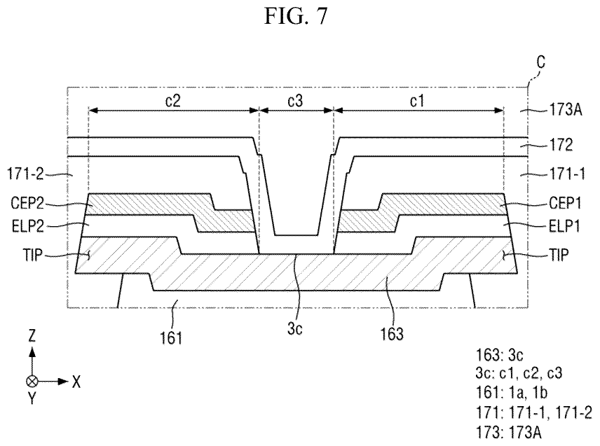

At the non-emission area NLA, the patterns of the first encapsulation layer 171 may be spaced apart from each other to expose surfaces of the emission layer EL, of the cathodes CE and of the second bank layer 163 to outside the first encapsulation layer 171. Referring to FIGS. 6 and 7, for example, the first inorganic layer 171-1 and the second inorganic layer 171-2 may be spaced apart from each other in the first direction (X-axis direction) with the second encapsulation layer 173 interposed between them in an area overlapping the non-emission area NLA.

The auxiliary encapsulation layer 172 of an embodiment may cover the first inorganic layer 171-1 and the second inorganic layer 171-2 along a profile formed by the first inorganic layer 171-1 and the second inorganic layer 171-2 in the portions overlapping the emission areas EA and the non-emission area NLA. In addition, the auxiliary encapsulation layer 172 may overlap a portion between the first inorganic layer 171-1 and the second inorganic layer 171-2 to contact an exposed portion of the second bank layer 163 in the portion overlapping the non-emission area NLA.

The auxiliary encapsulation layer 172 of the embodiment may include oxygen ions to increase the spreadability of an organic material. That is, the auxiliary encapsulation layer 172 of the embodiment may increase the spreadability of the second encapsulation layer 173 including an organic material. The first organic layer 173A and the third encapsulation layer 175 will not be described because they have been mentioned above.

FIG. 7 is an enlarged cross-sectional view of area ‘C’ in FIG. 6.

Referring to FIG. 7, the first surface 3c of the second bank layer 163 may be divided into a first part c1, a second part c2, and a third part c3 depending on a structure contacted by the second bank layer 163.

Specifically, the first part c1 of the second bank layer 163 may be a part (e.g., a distance or area) contacting the first organic pattern ELP1 and a part overlapping the first electrode pattern CEP1 and a tip TIP of the bank structure 160. In addition, the second part c2 may be a part contacting the second organic pattern ELP2 and a part overlapping the second electrode pattern CEP2 and a tip TIP of the bank structure 160. The third part c3 may be a part disposed between the first part c1 and the second part c2 and contacting the auxiliary encapsulation layer 172. The exposed portion of the upper surface of the second bank layer 163 may be defined at the third part c3.

In other words, the first part c1 may be a part overlapping the first electrode pattern CEP1 and the first inorganic layer 171-1, the second part c2 may be a part overlapping the first electrode pattern CEP1 and the second inorganic layer 171-12, and the third part c3 may not overlap the first organic pattern ELP1, the second organic pattern ELP2, the first electrode pattern CEP1, the second electrode pattern CEP2, the first inorganic layer 171-1, the second inorganic layer 171-2 and the tips TIP of the bank structure 160. That is, the second bank layer 163 which defines the tips TIP includes a first part c1 at which the first electrode pattern CEP1 contacts the bank, a second part c2 at which the second electrode pattern CEP2 contacts the bank, and a third part c3 at which the flow-control encapsulation layer (172) contacts the second bank layer 163 which is exposed at the non-emission area NLA.

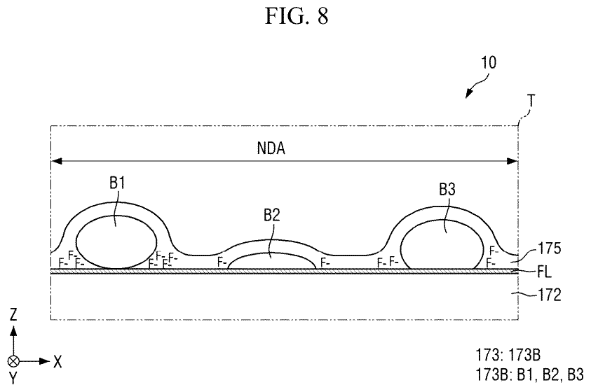

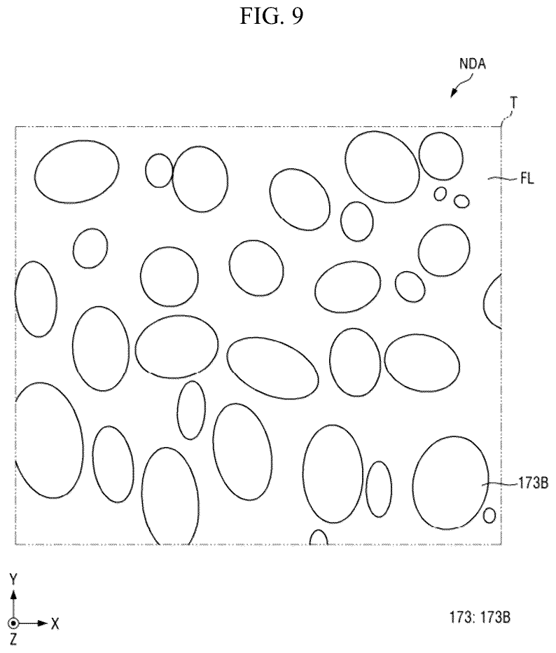

FIG. 8 is an enlarged cross-sectional view of area ‘T’ in FIG. 5. FIG. 9 is an enlarged plan view of area ‘T’ in FIG. 5.

Referring to FIG. 8, the fluorine ion layer FL may be disposed on the second via layer 127 in the portion overlapping the non-display area NDA. The fluorine ion layer FL may have a plurality of fluorine ions (F−) randomly disposed at a surface facing the second encapsulation layer 173.

The process of fabricating the display device 10 according to the embodiment may include an etching process which is repeated. In the display device 10 according to the embodiment, a fluorine-based etching material may be used in the etching process. The fluorine ion layer FL including fluorine ions (F−) exposed to outside the fluorine ion layer FL may be formed when a portion of the etching material remains without being removed after the etching process. The concentration of fluorine ions (F−) included in the fluorine ion layer FL may be adjusted by adjusting the concentration of fluorine-based chemicals used in the etching process.

Material forming the second organic layer 173B of the second encapsulation layer 173 may spread to the non-display area NDA to be disposed on the fluorine ion layer FL in the portion overlapping the non-display area NDA. The spreadability of the material forming the second organic layer 173B may be controlled by the fluorine ion layer FL. For example, the spreadability of the second organic layer 173B may be adjusted according to the concentration of fluorine ions (F−) disposed under and in contact with the second organic layer 173B. Specifically, when the concentration of fluorine ions (F−) within a planar area disposed under and in contact with the second organic layer 173B is relatively high, the spreadability of the material forming the second organic layer 173B may be reduced over such planar area. Accordingly, the second organic layer 173B may be formed similarly to, for example, a first form B1. In addition, when the concentration of fluorine ions (F−) disposed in a planar area under and in contact with the second organic layer 173B is relatively low, the spreadability of the second organic layer 173B may be increased over such planar area. Accordingly, the second organic layer 173B may be formed similarly to, for example, a second form B2. The second organic layer 173B may also be formed similarly to a third form B3 which is an intermediate form between the first form B1 and the second form B2, corresponding to an intermediate concentration of fluorine ions F−. However, this is only an example, and the second organic layer 173B can be formed in various forms in addition to the first form B1, the second form B2 and the third form B3 according to the concentration of fluorine ions (F−) disposed under and in contact with the second organic layer 173B.

The ‘form’ of the protruding pattern of the second encapsulation layer 173 may be defined by a contact area (e.g., a planar area) with the fluorine ion layer FL and/or a height (or thickness) along the thickness direction. Where first form B1 has a relatively small first contact area with the fluorine layer FL, the second form B2 has a second contact area larger than that of the first form B1, with a third contact area of the third form B3 being between those of the first form B1 and the second form B2. The height of the form may be inverse to the contact area, without being limited thereto.

The third encapsulation layer 175 may completely cover the second organic layer 173B. The third encapsulation layer 175 may contact the second organic layer 173B and the fluorine ion layer FL, at an exposed area of the fluorine ion layer FL which is between protruding patterns of the second encapsulation layer 173.

Since the display device 10 according to the embodiment includes the fluorine ion layer FL in the portion overlapping the non-display area NDA, the fluidity of a material forming the second encapsulation layer 173 can be controlled without a physical structure (generally, a dam structure occupying a planar area of the non-display area NDA) for controlling the fluidity of the second encapsulation layer 173. Therefore, in the display device 10 according to the embodiment, the planar area of the non-display area NDA can be minimized, thereby maximizing the planar area of the display area DA.

Referring to FIG. 9, the fluorine ion layer FL may be disposed in the entire portion overlapping the non-display area NDA in a plan view (e.g., in an entirety of the non-display area NDA. In a plan view, the second organic layer 173B of an embodiment may be disposed on the fluorine ion layer FL in the portion overlapping the non-display area NDA and may be formed in the form of a plurality of circular (planar) shapes spaced apart from each other in a direction along the non-display area NDA. Therefore, since the display device 10 according to the embodiment includes the fluorine ion layer FL in an entirety of the non-display area NDA in a plan view, the fluidity of material forming the second encapsulation layer 173 at the non-display area NDA can be controlled.

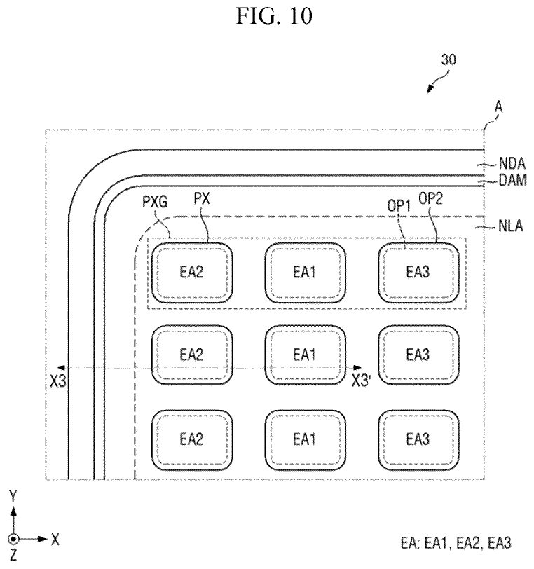

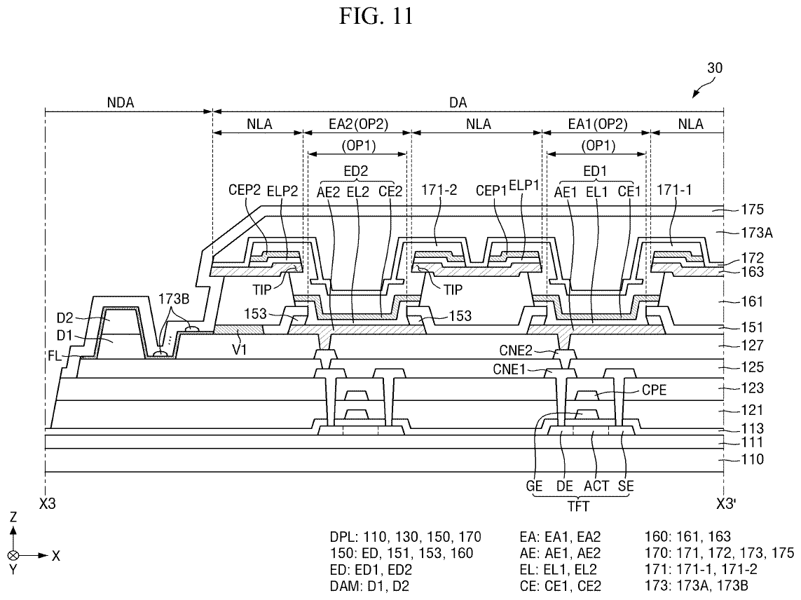

FIG. 10 is an enlarged cross-sectional view of area ‘A’ in FIG. 2 according to an embodiment. FIG. 11 is a schematic cross-sectional view of a display area DA taken along line X3-X3′ of FIG. 10.

Referring to FIGS. 10 and 11, a display device 30 according to an embodiment may be different from the display device 10 according to the previous embodiment in that it includes a dam DAM in a portion overlapping a non-display area NDA. The dam DAM may be a structure for preventing overflow an organic material disposed in a portion overlapping the display area DA from to the non-display area NDA toward an edge or end of the display device 30. The dam DAM may surround the display area DA in a plan view. In an embodiment, the dam DAM is further from the display area DA than the second organic layer 173B, and the fluorine ion layer FL extends from the second organic layer 173B and covers the dam DAM.

A structure overlapping the display area DA of the display device 30 according to the embodiment may be the same as that of the display device 10 according to the previous embodiment. That is, the display device 30 according to the embodiment may increase the spreadability of a second encapsulation layer 173 by including an auxiliary encapsulation layer 172 in the display area DA. Accordingly, the second encapsulation layer 173 of an embodiment may be in the form of a first organic layer 173A in the portion overlapping the display area DA. The auxiliary encapsulation layer 172 of an embodiment may not overlap the non-display area NDA. Other details will not be described again.

In some embodiments, the dam DAM may be disposed on a first via layer 125. The dam DAM may include a first sub-dam D1 and a second sub-dam D2. The first sub-dam D1 and the second sub-dam D2 may be sequentially stacked in the third direction (Z-axis direction). The first sub-dam D1 may include the same material as a second via layer 127 and may be disposed on the same layer as the second via layer 127. In addition, the second sub-dam D2 may include the same material as a first encapsulation layer 171 and may be disposed on the same layer as the first encapsulation layer 171. However, the present disclosure is not limited thereto, and the first sub-dam D1 and the second sub-dam D2 may also include the same material as the first encapsulation layer 171 depending on embodiments. Although the dam DAM has a double-layer structure in the drawings, it may also have a single-layer structure or a multilayer structure depending on embodiments.

A fluorine ion layer FL of an embodiment may be disposed in the portion overlapping the non-display area NDA. The fluorine ion layer FL of the embodiment may cover the first via layer 125, the second via layer 127, and the dam DAM. The fluorine ion layer FL of the embodiment may contact the first via layer 125, the second via layer 127, and the dam DAM. That is, the dam DAM of an embodiment may be covered by the fluorine ion layer FL.

Since the display device 30 according to the embodiment includes the dam DAM and the fluorine ion layer FL in the non-display area NDA, the spreadability of the second encapsulation layer 173 can be controlled. Accordingly, the second encapsulation layer 173 of the embodiment may be in the form of a second organic layer 173B in the portion overlapping the non-display area NDA.

Therefore, since the display device 30 according to the embodiment includes the fluorine ion layer FL on a surface of the dam DAM overlapping the non-display area NDA, the fluidity of the second encapsulation layer 173 can be controlled with the minimum dam DAM. Therefore, in the display device 30 according to the embodiment, the area of the non-display area NDA can be minimized, thereby maximizing the area of the display area DA.

FIGS. 12 through 22 are cross-sectional views illustrating a method of providing (or fabricating) the display device 10 of FIG. 5. FIGS. 12 through 22 are cross-sectional views illustrating processes and structures in a method of fabricating the display element layer 150 of FIG. 5. The formation order of each layer in the fabrication process of the display device 10 will now be described.

Referring to FIG. 12, a first anode AE1, a second anode AE2, sacrificial layers SFL, a pixel defining material layer 151L, a power line V1, and bank material layers 161L and 163L are provided (or formed) on a thin-film transistor layer 130. Although not illustrated in the drawing, the thin-film transistor layer 130 may be disposed on a substrate 110. The structure of the thin-film transistor layer 130 is the same as that described above with reference to FIG. 5, and thus a detailed description thereof will be omitted.

The first anode AE1 and the second anode AE2 may be spaced apart from each other on the thin-film transistor layer 130. The sacrificial layers SFL may be disposed on the first anode AE1 and the second anode AE2, respectively. The sacrificial layers SFL may prevent upper surfaces of the anodes AE from contacting an inorganic pixel defining layer 151 provided from the pixel defining material layer 151L.

The sacrificial layers SFL may include an oxide semiconductor. For example, the sacrificial layers SFL may include at least one of indium gallium zinc oxide (IGZO), zinc tin oxide (ZTO), and indium tin oxide (ITO).

The pixel defining material layer 151L may cover the sacrificial layers SFL and a portion of the thin-film transistor layer 130 which is exposed to outside anode electrodes AE and the sacrificial layer SFL, and the bank material layers 161L and 163L may entirely cover the pixel defining material layer 151L and the power line V1. The bank material layers 161L and 163L may include a first bank material layer 161L and a second bank material layer 163L. The first bank material layer 161L may be directly disposed on the pixel defining material layer 151L, and the second bank material layer 163L may be directly disposed on the first bank material layer 161L.

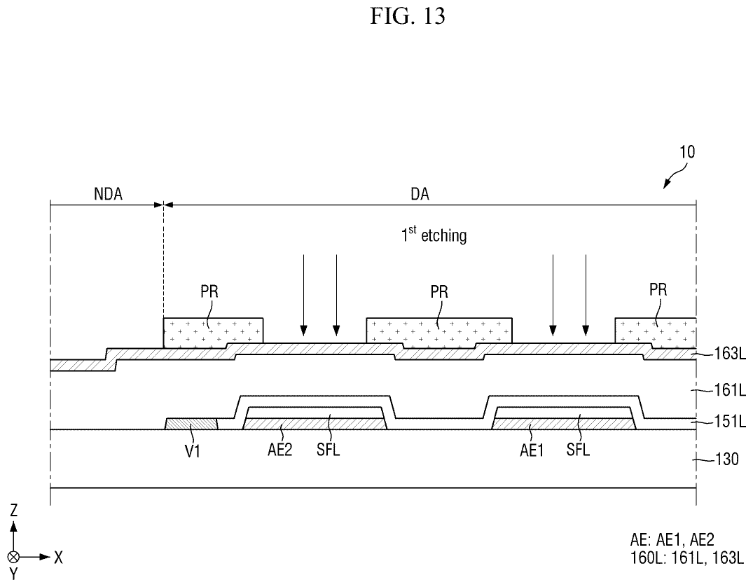

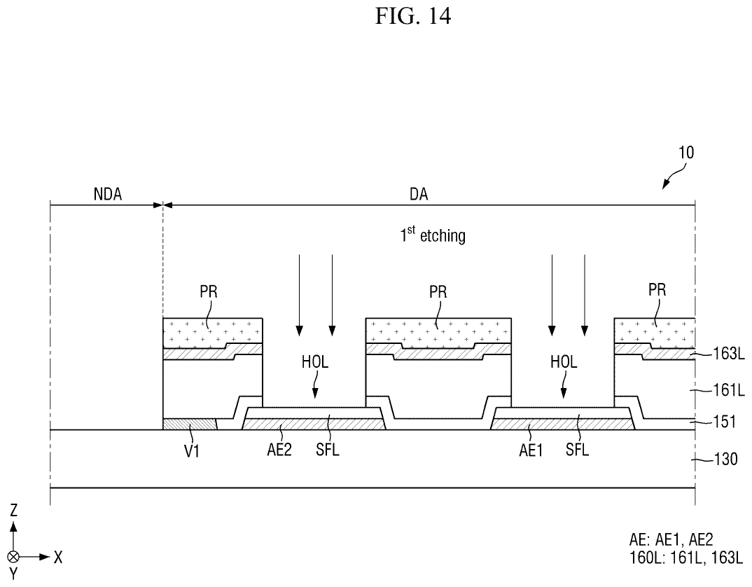

Referring to FIGS. 13 and 14, a plurality of photoresists PR are formed on the second bank material layer 163L, and a first etching process for partially removing portions of the first bank material layer 161L and the second bank material layer 161L is performed using the photoresists PR as a mask. The photoresists PR may expose portions overlapping the anodes AE and may be spaced apart from each other.

In the first etching process, holes HOL may be formed in the second bank material layer 163L, the first bank material layer 161L and the pixel defining material layer 151L, at portions overlapping the first anode AE1 and the second anode AE2, respectively, and a display area DA and a non-display area NDA may be defined. The thin-film transistor layer 130 may be exposed by the first etching process. In addition, the pixel defining material layer 151L may be formed into the inorganic pixel defining layer 151 illustrated in FIG. 5.

In an embodiment, the first etching process may be performed as a dry etching process. As the first etching process is performed as a dry etching process, the bank material layers 161L and 163L including different metal materials, and the pixel defining material layer 151L, may be etched, thereby exposing the sacrificial layers SFL overlapping the anodes AE to outside a stacked structure of remaining portions of the second bank material layer 163L, the first bank material layer 161L and the pixel defining material layer 151L (e.g., the inorganic pixel defining layer 151).

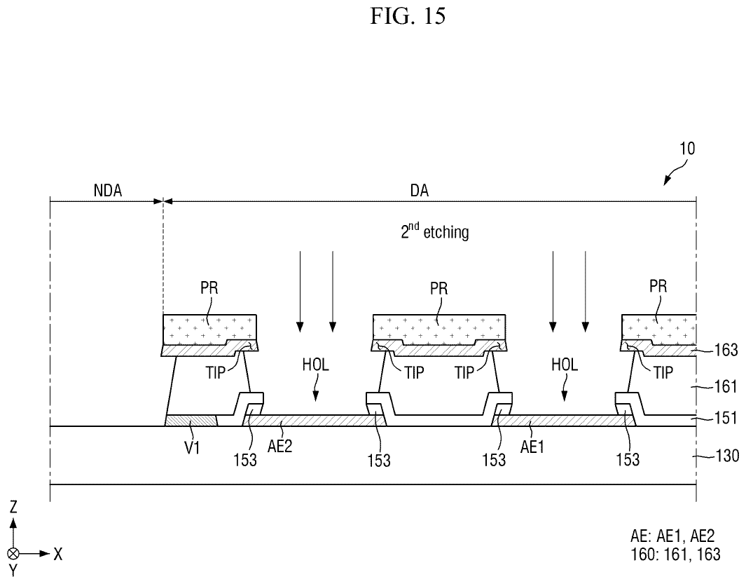

Referring to FIG. 15, a second etching process is performed at the holes HOL to etch material at the inside of the holes HOL and overlapping the anodes AE. In an embodiment, the second etching process may be performed as a wet etching process.

In an embodiment, the first bank material layer 161L may have a higher etch rate than the second bank material layer 163L. That is, the first bank material layer 161L may be etched faster than the second bank material layer 163L. Accordingly, side surfaces of the second bank material layer 163L which form bank holes may have or define tips TIP protruding further than side surfaces of the first bank material layer 161L toward the holes HOL. An undercut may be formed by the first bank material layer 161L together with each tip TIP of the second bank material layer 163L. In the second etching process, the first bank material layer 161L may be formed into the first bank layer 161 illustrated in FIG. 5, and the second bank material layer 163L may be formed into the second bank layer 163, where the first bank layer 161 and the second bank layer 163 together form banks of a bank layer having the bank holes between the banks.

At the same time, the sacrificial layers SFL disposed on the anodes AE may be

partially removed. However, ends of the sacrificial layers SFL may not be completely removed, but may remain as residual patterns 153 in spaces between the inorganic pixel defining layer 151 and the anodes AE. The residual patterns 153 may be overlapped by the tips TIP in the third direction (Z-axis direction).

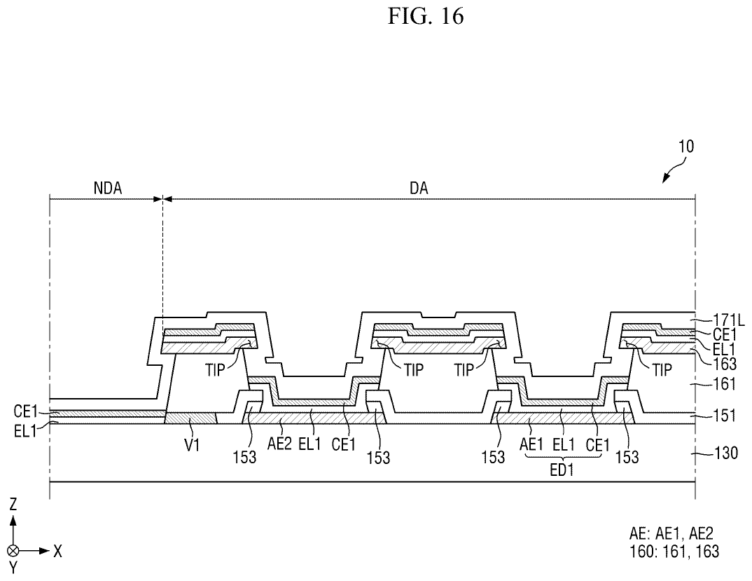

Referring to FIG. 16, a first light emitting layer EL1 and a first cathode CE1 are deposited on the first anode AE1. In an embodiment, the first light emitting layer EL1 and the first cathode CE1 may be formed through a thermal evaporation process. In the display device 10 according to the embodiment, since a bank structure 160 includes the tips TIP, the first light emitting layer EL1 and the first cathode CE1 can be formed as a pattern on the first anode AE1 without a fine metal mask.

However, a deposition process for forming the first light emitting layer EL1 may be performed at an angle of about 45 degrees to about 50 degrees relative to the upper surfaces of the anodes AE. Accordingly, the first light emitting layer EL1 may be formed to fill the spaces between the anodes AE and the inorganic pixel defining layer 151 and may be extended along the side surfaces of the first bank layer 161 overlapped by the tips TIP.

A deposition process for forming the first cathode CE1 of an embodiment may be performed at an angle of about 30 degrees or less relative to the upper surfaces of the anodes AE. In other words, the deposition process for forming the first cathode CE1 may be performed at an angle relatively closer to a horizontal direction (e.g., parallel to an X-Y plane) than the deposition process for forming the first light emitting layer EL1. Accordingly, the first cathode CE1 may completely cover the first light emitting layer EL1 and may also extend along the side surfaces of the first bank layer 161 covered by the tips TIP. Through this process, a first light emitting element ED1 may be formed.

In an embodiment, portions of material layers from which the first light emitting layer EL1 and the first cathode CE1 are formed may be disposed not only on the first anode AE1, but also on the second anode AE2 and the second bank layer 163 in a portion overlapping the display area DA and on the thin-film transistor layer 130 in a portion overlapping the non-display area NDA. In other words, in an embodiment, the first light emitting layer EL1 and the first cathode CE1 may be deposited on an entirety of a stacked structure below such material layers.

A first encapsulation material layer 171L covering the first cathode CE1 is formed on the entire surface of the underlying stacked structure. The first encapsulation material layer 171L may be formed using a chemical vapor deposition (CVD) process. The first encapsulation material layer 171L may form a uniform layer (e.g., having a constant thickness) regardless of steps of structures thereunder. For example, the first encapsulation material layer 171L may cover a step formed by the first light emitting element ED1 and may also cover an undercut portion formed between the first bank layer 161 and each tip TIP. The first encapsulation material layer 171L of an embodiment may be deposited in the entire portions overlapping the display area DA and the non-display area NDA.

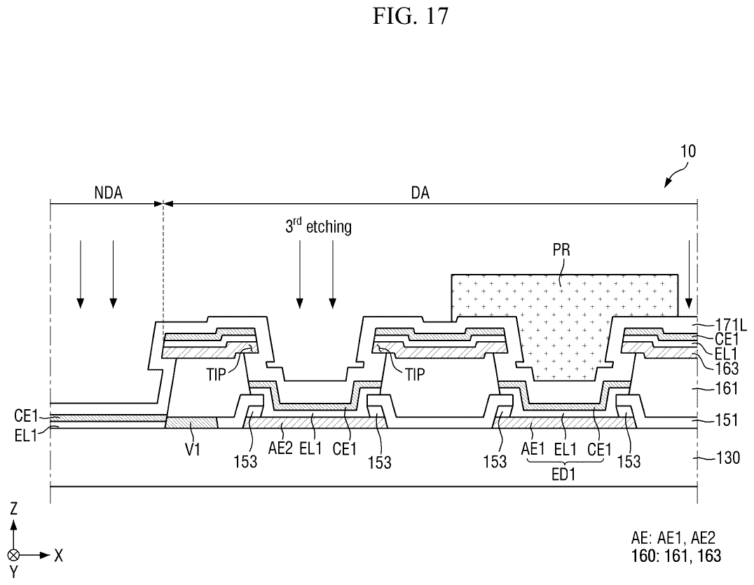

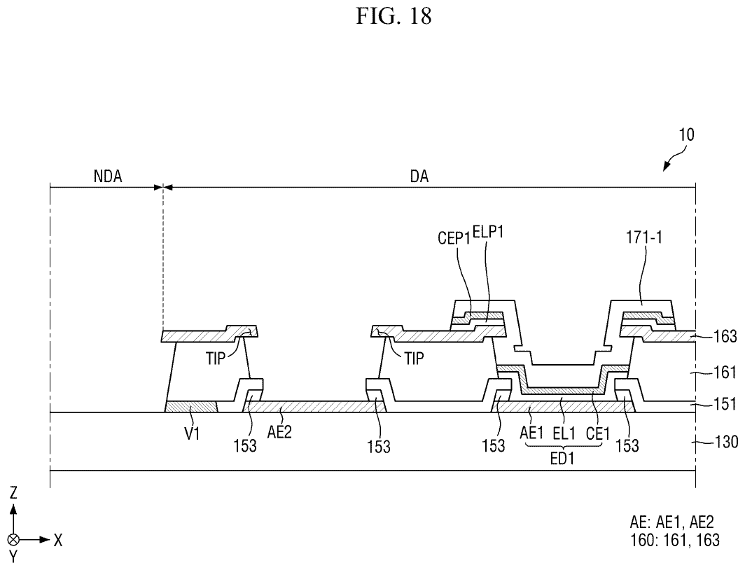

Referring to FIGS. 17 and 18, a photoresist PR is formed corresponding to the first light emitting element ED1 and a portion around the first light emitting element ED1. Then, a third etching process is performed to partially etch layers at an area other than an area corresponding to the first light emitting element ED1 and the portion which is around the first light emitting element ED1. For example, in the third etching process, a wet etching process and a dry etching process may be alternately performed. In the third etching process, the first light emitting layer EL1, the first cathode CE1, and material of the first encapsulation material layer 171L in a portion where the photoresist PR is not formed may all be removed.

Through the third etching process, the first encapsulation material layer 171L may be formed into a first inorganic layer 171-1, and materials providing the first light emitting layer EL1 and the first cathode CE1 disposed on the second bank layer 163 may be further formed into a first organic pattern ELP1 and a first electrode pattern CEP1.

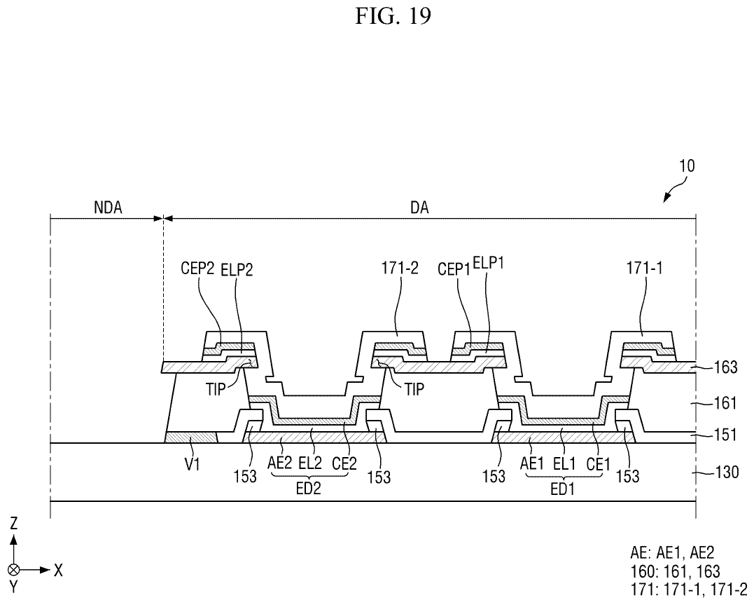

Referring to FIG. 19, the processes described above in FIGS. 16 through 18 are repeated to form a second light emitting element ED2 after forming the previous light emitting element (e.g., the first light emitting element ED1). Specifically, a second light emitting layer EL2, a second cathode CE2, and a first encapsulation material layer 171L are deposited on the entire surface of an underlying stacked structure. The materials providing the second light emitting layer EL2, the second cathode CE2, and the first encapsulation material layer 171L may not only be formed on the second anode AE2, but also be deposited on the first inorganic layer 171-1 and the second bank layer 163 in the portion overlapping the display area DA and be deposited on the thin-film transistor layer 130 in the portion overlapping the non-display area NDA. A photoresist PR may be formed corresponding to the second light emitting element ED2 and a portion around the second light emitting element ED2, and material portions at an area other than the second light emitting element ED2 and the portion around the second light emitting element ED2 may be partially etched to form the second light emitting element ED2, a second inorganic layer 171-2, a second organic pattern ELP2, and a second electrode pattern CEP2.

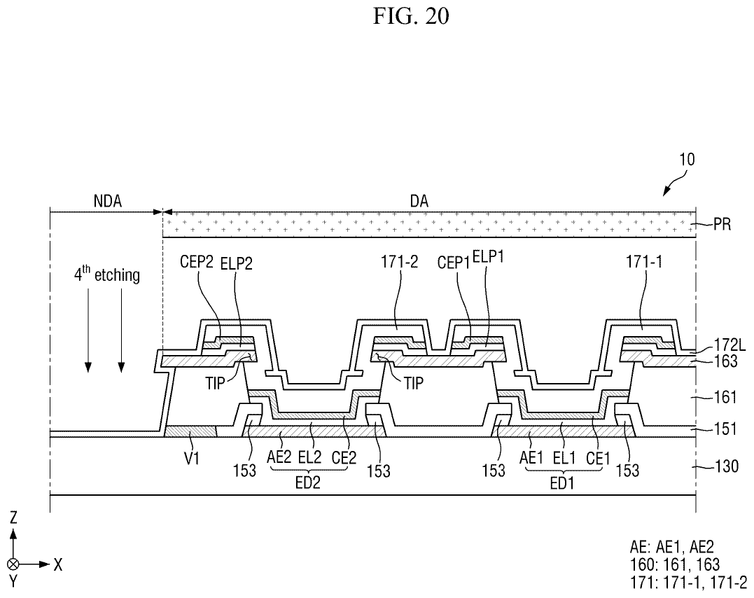

Referring to FIG. 20, an auxiliary encapsulation material layer 172L is entirely deposited in the display area DA and the non-display area NDA. The auxiliary encapsulation material layer 172L may completely cover structures thereunder. The auxiliary encapsulation material layer 172L may include oxygen ions to increase the spreadability of a second encapsulation layer 173. The oxygen ion content of the auxiliary encapsulation material layer 172L may be about 35% or more when measured by Fourier transform infrared spectroscopy (FT-IR). A material providing the second encapsulation layer 173 may having a flowability (e.g., a first flowability) relative to a material providing the auxiliary encapsulation material layer 172L.

A fourth etching process is performed to remove a portion of the auxiliary encapsulation material layer 172L which is disposed in the portion overlapping the non-display area NDA. For example, the fourth etching process may be a dry etching process. The portion of the auxiliary encapsulation material layer 172L at the non-display area NDA may be etched by using a photoresist PR as a mask, without being limited thereto.

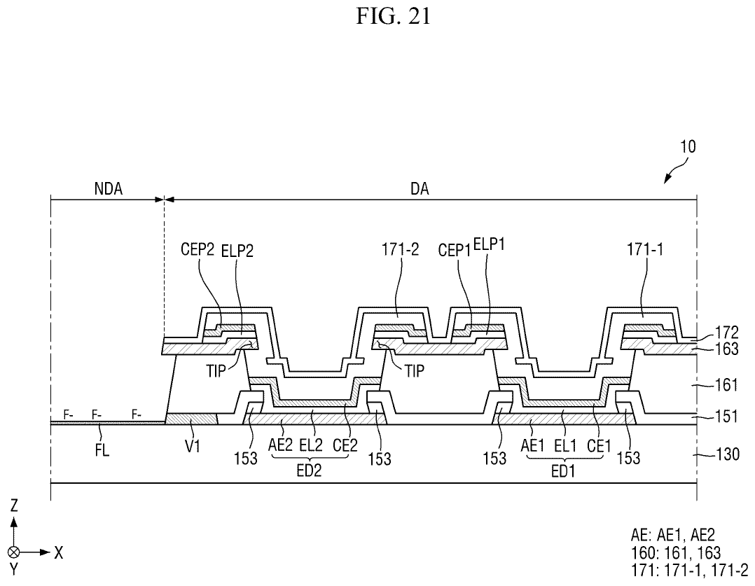

Referring to FIG. 21, the auxiliary encapsulation material layer 172L overlapping the non-display area NDA may be removed through the fourth etching process. Accordingly, the auxiliary encapsulation material layer 172L may be formed into the auxiliary encapsulation layer 172 illustrated in FIG. 5.

The fourth etching process of an embodiment may use fluorine-based chemicals. Through the fourth etching process, the display device 10 according to embodiment may have a fluorine ion layer FL in the portion overlapping the non-display area NDA. The fluorine ion layer FL may refer to a layer having fluorine ions (F−) from the etchant including fluorine which remain on an exposed surface in the non-display area NDA, after the fourth etching process is completed. Generally, the fluorine ions (F−) remaining on the surface may control the second encapsulation layer 173 to have low spreadability.

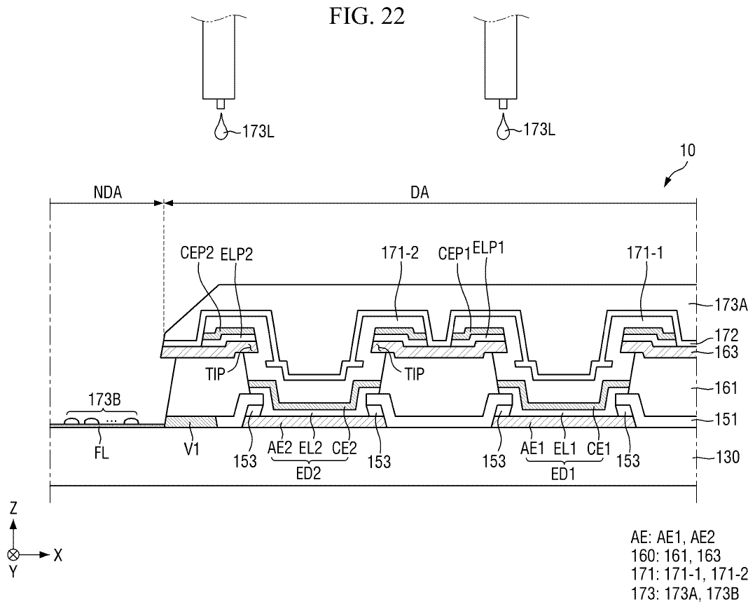

Referring to FIG. 22, a second encapsulation material layer 173L is applied on the entire surface of the first encapsulation layer 171 and the fluorine ion layer FL. The second encapsulation material layer 173L may have high spreadability relative to the auxiliary encapsulation layer 172 in the portion overlapping the display area DA and may be formed into the first organic layer 173A illustrated in FIG. 5. In addition, the second encapsulation material layer 173L may have low spreadability relative to the fluorine layer FL (otherwise referred to as a fluorine ion layer FL) in the portion overlapping the non-display area NDA and may be formed into the second organic layer 173B illustrated in FIG. 5. The auxiliary encapsulation layer 172 and the fluorine layer FL may together provide a flow-control layer having a surface along which material providing the second encapsulation layer 173 spreads. The flow-control layer may have a first flowability relative to the material providing the second encapsulation layer 173, at the auxiliary encapsulation layer 172, and may have a second flowability relative to the material providing the second encapsulation layer 173, at the fluorine ion layer FL, where the second flowability is less than the first flowability.

The second organic layer 173B may be formed including multiple pieces or discrete patterns spaced apart from each other, where the discrete patterns may have a round shape in the plan view. That is, the first organic layer 173A and the second organic layer 173B included in the second encapsulation layer 173 may be formed in the same process and may have different shapes (e.g., along a planar direction and along a thickness direction) depending on a shape and a profile of the underlying structures.

As described above, the display device 10 according to the embodiment may have the auxiliary encapsulation layer 172 only in the display area DA and have the fluorine ion layer FL only in the non-display area NDA. Therefore, the spreadability of material providing the second encapsulation layer 173 can be controlled even without a physical structure. Accordingly, since a physical structure for controlling spreadability is obviated at the non-display area NDA of the display device 10 according to the embodiment, the area of the non-display area NDA can be designed to be minimal.

Although not illustrated in the drawings, a third encapsulation layer 175 which completely covers the second encapsulation layer 173 may be formed to produce the display device 10 illustrated in FIG. 5.

A display device 10 according to an embodiment includes a flow-control layer having a fluorine ion layer FL in a portion overlapping a non-display area NDA and an auxiliary encapsulation layer 172 in a portion overlapping a display area DA. Therefore, the spreadability of a material providing an organic encapsulation layer can be controlled. That is, in the display device 10 according to the embodiment, since the spreadability of the material providing the organic encapsulation layer can be flow-controlled without a physically structure in the portion overlapping the non-display area NDA, the area of the non-display area NDA can be minimized.

In an embodiment, a display device 10 includes a display area DA including an emission area EA including a light emitting element ED, a non-emission area NLA including a pixel defining layer 151 defining a first opening OP1 corresponding to the light emitting element ED, and a bank (161+163) on the pixel defining layer 151 and defining a second opening OP2 corresponding to the first opening OP1, the bank including a first bank layer 161 contacting the pixel defining layer 151, and a second bank layer 163 on the first bank layer 161, the second bank layer 163 having a tip TIP which protrudes further than the first bank layer 161 at the second opening OP2, and a first encapsulation layer 171 on the light emitting element ED and the bank layer, a non-display area NDA adjacent to the display area DA, a flow-control layer (172+FL) in the display area DA and in the non-display area NDA, the flow-control layer including an auxiliary encapsulation layer 172 in the display area DA, and a fluorine ion layer FL in the non-display area NDA, and a second encapsulation layer 173 extended along the flow-control layer, in the display area DA and in the non-display area NDA.

In addition, the display device 10 according to the embodiment may include a bank structure 600 including tips TIP protruding toward emission areas EA and defining a bank hole corresponding to light emission areas. Therefore, the display device 10 according to the embodiment may form a high-resolution display device through a pattern process.

In an embodiment a display device 10 includes emission areas ED respectively including anodes AE of light emitting elements ED, and a non-emission area NLA between the emission areas EA, the non-emission area including a pixel defining layer 151 and a bank on the pixel defining layer 151, the bank including a first bank layer 161 on the pixel defining layer 151, a second bank layer 163 on the first bank layer 161, the second bank layer 163 defining tips TIP which protrude further than the first bank layer 161 at respective emission areas EA, cathodes CE of the light emitting elements ED, the cathodes CE respectively on the anodes AE and contacting the first bank layer 161 of the bank, an encapsulation layer on the cathodes CE and on the bank, the encapsulation layer including first encapsulation layers 171 respectively on the cathodes CE and spaced apart from each other at the non-emission area NLA to expose the second bank layer 163 to outside the first encapsulation layers 171, the first encapsulation layers 171 extending from the cathodes CE and along the first bank layer 161 of the bank, and a flow-control encapsulation layer (172) covering the first encapsulation layers 171 and contacting the second bank layer 163 which is exposed at the non-emission area NLA.

A method of providing a display device 10 includes providing an anode AE of a light emitting element ED and a sacrificial layer SFL which is on the anode ED, in an emission area EA within a display area DA of the display device 10, providing a pixel defining material layer 151L covering the anode AE and the sacrificial layer SFL in the emission area EA, the pixel defining material layer 151L extending from the emission area EA to a non-emission area NLA adjacent to the emission area EA and to a non-display area NDA adjacent to the display area DA, providing a bank material layer (161L and 163L) completely covering the pixel defining material layer 151L (FIG. 12, for example), providing a hole HOL in the pixel defining material layer 151L and the bank material layer by a first etching process using a photoresist PR on the bank material layer, the hole HOL corresponding to the anode AE, the providing of the hole HOL defining a bank (161 and 163) from the bank material layer which has a tip TIP forming an undercut structure of the bank at the hole HOL, the anode being exposed to outside the bank at the hole HOL (FIGS. 13-15, for example), providing a light emitting material layer and a cathode material layer covering the anode AE and the bank, providing a first encapsulation material layer 171L on an entirety of the cathode material layer (FIG. 16, for example), removing respective portions of the light emitting material layer, the cathode material layer and the first encapsulation material layer except for portions corresponding to the emission area EA and an area which extends around the emission area EA, the removing the respective portions defining a first encapsulation layer 171 from the first encapsulation material layer, the first encapsulation layer overlapping the emission area EA and the area which extends around the emission area EA (FIGS. 17-19, for example), providing a flow-control material layer on the first encapsulation layer 171 and the bank, to overlap both the display area DA and the non-display area NDA, removing a portion of the flow-control material layer which is in the non-display area NDA, through a second etching process including an etchant having fluorine ions, to define a flow-control layer including an auxiliary encapsulation layer 172 in the display area DA and a fluorine ion layer FL in the non-display area NDA (FIGS. 20 and 21, for example), and providing a second encapsulation material layer 173L on the auxiliary encapsulation layer 172 which is in the display area DA, the second encapsulation material layer 173L spreading along the display area DA and to the fluorine ion layer FL in the non-display area NDA to provide a second encapsulation layer 173 in both the display area DA and the non-display area NDA.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a display area comprising
an emission area including a light emitting element;
a non-emission area including:
a pixel defining layer defining a first opening corresponding to the light emitting element, and
a bank on the pixel defining layer and defining a second opening corresponding to the first opening, the bank including:
a first bank layer contacting the pixel defining layer, and
a second bank layer on the first bank layer, the second bank layer having a tip which protrudes further than the first bank layer at the second opening; and
a first encapsulation layer on the light emitting element and the bank;
a non-display area adjacent to the display area;
a flow-control layer in the display area and in the non-display area, the flow-control layer comprising:
an auxiliary encapsulation layer in the display area, and
a fluorine ion layer in the non-display area; and
a second encapsulation layer extended along the flow-control layer, in the display area and in the non-display area.

2. The display device of claim 1, wherein the second encapsulation layer comprises:
a first organic layer contacting the auxiliary encapsulation layer, in the display area, and
a second organic layer contacting the fluorine ion layer, in the non-display area.

3. The display device of claim 2, wherein
a material of each of the first organic layer and the second organic layer has a spreadability relative to the flow-control layer, and
the spreadability of the material of the first organic layer and the spreadability of the material of the second organic layer are different from each other.

4. The display device of claim 3, wherein the spreadability of the material of the first organic layer is higher than the spreadability of the material of the second organic layer.

5. The display device of claim 4, wherein the first organic layer and the second organic layer are spaced apart from each other and are respective portions of a same material layer.

6. The display device of claim 2, wherein
a material of each of the first organic layer and the second organic layer has a spreadability relative to the flow-control layer,
the spreadability of the material of the first organic layer is defined by contact of the material of the first organic layer along the auxiliary encapsulation layer, and
the spreadability of the material of the second organic layer is defined by contact of the material of the second organic layer along the fluorine ion layer.

7. The display device of claim 6, wherein the second organic layer comprises discrete patterns spaced apart from each other along the fluorine ion layer, the discrete patterns having a round shape in a plan view.

8. The display device of claim 1, wherein the fluorine ion layer comprises fluorine ions at a surface of the fluorine ion layer which faces the second encapsulation layer.

9. The display device of claim 8, wherein the auxiliary encapsulation layer comprises silicon oxide or silicon oxynitride.

10. The display device of claim 9, wherein the auxiliary encapsulation layer has an oxygen content of about 35% or more.

11. The display device of claim 1, wherein the first opening is completely within the second opening in a plan view.

12. The display device of claim 2, further comprising a third encapsulation layer on the second encapsulation layer,
wherein in the non-display area, the third encapsulation layer contacts the second organic layer and the fluorine ion layer and completely covers the second organic layer and the fluorine ion layer.

13. The display device of claim 2, the non-display area further comprises:
a dam further from the display area than the second organic layer, and
the fluorine ion layer extending from the second organic layer and covering the dam.

14. A display device comprising:
emission areas respectively including anodes of light emitting elements, and
a non-emission area between the emission areas, the non-emission area including:
a pixel defining layer; and
a bank on the pixel defining layer, the bank including:
a first bank layer on the pixel defining layer; and
a second bank layer on the first bank layer, the second bank layer defining tips which protrude further than the first bank layer at respective emission areas;
cathodes of the light emitting elements, the cathodes respectively on the anodes and contacting the first bank layer of the bank;
an encapsulation layer on the cathodes and on the bank, the encapsulation layer including:
first encapsulation layers respectively on the cathodes and spaced apart from each other at the non-emission area to expose the second bank layer to outside the first encapsulation layers, the first encapsulation layers extending from the cathodes and along the first bank layer of the bank; and
a flow-control encapsulation layer covering the first encapsulation layers and contacting the second bank layer which is exposed at the non-emission area.

15. The display device of claim 14, wherein
the anodes comprise a first anode and a second anode spaced apart from each other with the pixel defining layer therebetween;
the cathodes which contact the first bank layer comprise a first cathode on the first anode and a second cathode on the second anode; and
the first cathode and the second cathode are electrically connected to each other by the first bank layer.

16. The display device of claim 15, further comprising a conductive pattern layer including:
the first cathode and the second cathode in the respective emission areas; and
in the non-emission area:
a first electrode pattern on the bank and spaced apart from the first cathode; and
a second electrode pattern on the bank and spaced apart from the second cathode.

17. The display device of claim 16, wherein the second bank layer which defines the tips comprises:
a first part at which the first electrode pattern contacts the bank;
a second part at which the second electrode pattern contacts the bank; and
a third part at which the flow-control encapsulation layer contacts the second bank layer which is exposed at the non-emission area.

18. The display device of claim 17, wherein the first encapsulation layers comprise:
a first inorganic layer covering the first cathode and the first electrode pattern; and
a second inorganic layer covering the second cathode and the second electrode pattern.

19. A method of providing a display device, the method comprising:
providing an anode of a light emitting element and a sacrificial layer which is on the anode, in an emission area within a display area of the display device;
providing a pixel defining material layer covering the anode and the sacrificial layer in the emission area, the pixel defining material layer extending from the emission area to a non-emission area adjacent to the emission area and to a non-display area adjacent to the display area;
providing a bank material layer completely covering the pixel defining material layer;
providing a hole in the pixel defining material layer and the bank material layer by a first etching process using a photoresist on the bank material layer, the hole corresponding to the anode;
the providing of the hole defining a bank from the bank material layer which has a tip forming an undercut structure of the bank at the hole, the anode being exposed to outside the bank at the hole;
providing a light emitting material layer and a cathode material layer covering the anode and the bank;
providing a first encapsulation material layer on an entirety of the cathode material layer;
removing respective portions of the light emitting material layer, the cathode material layer and the first encapsulation material layer except for portions corresponding to the emission area and an area which extends around the emission area;
the removing the respective portions defining a first encapsulation layer from the first encapsulation material layer, the first encapsulation layer overlapping the emission area and the area which extends around the emission area;
providing a flow-control material layer on the first encapsulation layer and the bank, to overlap both the display area and the non-display area;
removing a portion of the flow-control material layer which is in the non-display area, through a second etching process including an etchant having fluorine ions, to define a flow-control layer including an auxiliary encapsulation layer in the display area and a fluorine ion layer in the non-display area; and
providing a second encapsulation material layer on the auxiliary encapsulation layer which is in the display area, the second encapsulation material layer spreading along the display area and to the fluorine ion layer in the non-display area to provide a second encapsulation layer in both the display area and the non-display area.

20. The method of claim 19, wherein the fluorine ion layer does not overlap the display area and contacts the second encapsulation layer.
